(19) United States
(12) Patent Application Publication
(10) Pub. No.: US 2026/0362720 A1
(43) Pub. Date: Nov. 12, 2026

(54) CAPACITOR HAVING A BOTTOM CAPACITOR PLATE WITH A ROUGH UPPER SURFACE, SEMICONDUCTOR DEVICE INCLUDING THE CAPACITOR AND METHODS OF FORMING THE SAME

(71) Applicant: Taiwan Semiconductor Manufacturing Company Limited, Hsinchu (TW)

(72) Inventors: I-Che Lee, Taipei City (TW); Pin-Ju Chen, Hsinchu City (TW); Wei-Gang Chiu, New Taipei City (TW); Yen-Chieh Huang, Hsinchu (TW); Kai-Wen Cheng, Taichung City (TW); Huai-Ying Huang, Jhonghe City (TW); Yu-Ming Lin, Hsinchu City (TW)

(21) Appl. No.: 19/746,874

(22) Filed: Jul. 20, 2026

Related U.S. Application Data
(62) Division of application No. 18/354,680, filed on Jul. 19, 2023.

(51) Int. Cl. H10D 1/00; H10B 12/00; H10D 1/68; H10W 20/40

(52) U.S. Cl. CPC H10D 1/042; H10B 12/033; H10B 12/05; H10D 1/716; H10W 20/496

(57) ABSTRACT

A capacitor includes a bottom capacitor plate including a rough upper surface with a root mean square (RMS) surface roughness of at least 1.14, a capacitor dielectric layer on the bottom capacitor plate and contacting the rough upper surface of the bottom capacitor plate, and an upper capacitor plate on the capacitor dielectric layer. A semiconductor device includes a transistor located on a substrate, a dielectric layer on the transistor, and a capacitor in the dielectric layer and including a bottom capacitor plate connected to a source region of the transistor and having a rough upper surface with a root mean square (RMS) surface roughness of at least 1.14.

### CROSS-REFERENCE TO RELATED APPLICATIONS

This application is a divisional patent application of U.S. Application No. 18/354,680, entitled “Capacitor Having a Bottom Capacitor Plate with a Rough Upper Surface, Semiconductor Device Including the Capacitor and Methods Of Forming The Same” filed Jul. 19, 2023, which is hereby incorporated by reference in its entirety for all purposes.

### BACKGROUND

Semiconductor devices that utilize on-chip capacitors may include, for example, dynamic random access memories (DRAMs), voltage controlled oscillators (VCOs), phase-locked loops (PLL), operational amplifiers (OP-AMPS), and switching (or switched) capacitors (SCs). Such on-chip capacitors may also be usable to decouple digital and analog integrated circuits (ICs) from electrical noise generated in or transmitted by other components of a semiconductor device.

Capacitor structures for ICs have evolved from the initial parallel plate capacitor structures, having two conductive layers separated by a dielectric, to more complex capacitor designs that may meet specifications for high capacitance in increasingly smaller devices. These more complex designs include, for example, metal-oxide-metal (MOM) capacitor designs and interdigitated finger MOM capacitor structures. Capacitors utilized in DRAM devices, for example, may include trench capacitors where the capacitor dielectric may separate the capacitor plates within trenches.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a vertical cross-sectional view of a semiconductor device according to one or more embodiments.

FIG. 1B is a detailed vertical cross-sectional view of a lower corner region of the capacitor according to one or more embodiments.

FIG. 1C is a horizontal cross-sectional view of the capacitor according to one or more embodiments.

FIG. 2A is an intermediate structure after formation of the gate structure and source/drain regions, according to one or more embodiments.

FIG. 2B is an intermediate structure after formation of the first source/drain contact, second source/drain contact and gate electrode contact, according to one or more embodiments.

FIG. 2C is an intermediate structure after formation of the second dielectric layer and the trench, according to one or more embodiments.

FIG. 2D is an intermediate structure after formation of the bottom capacitor plate, according to one or more embodiments.

FIG. 2E is an intermediate structure after formation of the capacitor dielectric layer and the upper capacitor plate, according to one or more embodiments.

FIG. 2F is an intermediate structure after formation of the third dielectric layer according to one or more embodiments.

FIG. 3 illustrates a method of making a semiconductor device, according to one or more embodiments.

FIG. 4 is a detailed cross-sectional view of a portion of the capacitor having an alternative design according to one or more embodiments.

FIG. 5 is a vertical cross-sectional view of the semiconductor device having a first alternative design according to one or more embodiments.

FIG. 6 is a vertical cross-sectional view of the semiconductor device having a second alternative design according to one or more embodiments.

FIG. 7 is a schematic illustration of the semiconductor device having a third alternative design according to one or more embodiments.

FIG. 8 is a schematic illustration of the semiconductor device having a fourth alternative design according to one or more embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range. The term "source/drain region" may refer to a source or a drain, individually or collectively depending upon the context.

A typical DRAM device may include arrays of memory cells that may each comprise a charge storage device (e.g., a capacitor) coupled to a charge accessing device (e.g., a field effect transistor (FET), metal oxide semiconductor field effect transistor (MOSFET), etc.). Such devices may be referred to as a 1T1C device (one transistor, one capacitor device). The source electrode of the transistor may be connected to one plate of the storage capacitor. The drain electrode of the transistor may be connected to a conducting bit line. The gate electrode of the transistor may be connected to a conducting word line.

In operation, a logical 1 or a 0 may be written into or read out of the memory cell of the DRAM device. In order to access or select a specific memory cell, the intersecting word line and bit line for the transistor associated with the specified memory cell may be energized to write in or read out the value stored on the capacitor coupled to the access/select transistor. In a write operation, by applying a given potential to the word line turns on the access transistor and a given charge applied to the bit line will then be deposited on the capacitor plate and stored. Conversely, during a read operation, the word line again activates the access transistor and the presence of the charge in the capacitor may be sensed by appropriate circuitry and identified as a 1 or 0.

Some DRAM devices may utilize a planar-type storage capacitor. However, such DRAM devices that utilize a planar-type storage capacitor may occupy a large wafer surface area. Other DRAM devices may use a stacked capacitor to achieve higher capacitance with a reduced size. The stacked capacitor may be formed on top of the transistor which allows a smaller cell to be built without losing storage capacity.

Still other DRAM devices may use a trench capacitor to achieve higher capacitance with a reduced size. The trench capacitor may be formed in a trench or cavity that extends vertically into the substrate of an integrated circuit, and may be formed through a variety of etching processes. Such trench capacitors may increase plate area and, hence, capacitance, through an increased vertical extension rather than by horizontal extension of the metal plate surface. A first plate of such a trench capacitor may be defined by the surface of the inner wall of the doped region of the substrate within which the trench may be formed. Although such an inner wall forms the plate boundary, charge may also be stored within a depletion region formed beneath the wall surface and extending into the doped substrate. The opposing second plate of the trench capacitor, which may also be a storage plate, may be a conductive core that may be formed within the trench. An oxide layer may first be formed over the inner trench wall to serve as a dielectric medium and to insulate the first plate from the second plate.

Traditional DRAM devices may occupy a significant amount of silicon substrate area. They may also require a complex manufacturing process that utilizes a high temperature, resulting in a high manufacturing cost. In addition, the capacitor utilized by the DRAM devices for information storage may have a relatively low capacitance. For example, DRAM devices utilizing a plate capacitor may require a large area and may not reliably achieve a large capacitance. DRAM devices utilizing a finger capacitor may require a large area, have a limitation of pitch and a low dielectric constant insulator. DRAM devices utilizing a trench capacitor may suffer a limitation on via size, a limitation on via depth and a limitation on high-k dielectric thickness.

One or more embodiments of the present disclosure may include a capacitor having a significantly greater capacitance than a traditional capacitor. The capacitor may include a bottom capacitor plate including a rough upper surface with a root mean square (RMS) surface roughness of at least 1.14. The rough upper surface may increase a surface area of the bottom capacitor plate, and the increased surface area may result in an increased capacitance of the capacitor. The capacitor may further include a capacitor dielectric layer on the bottom capacitor plate and contacting the rough upper surface of the bottom capacitor plate, and an upper capacitor plate on the capacitor dielectric layer.

One or more embodiments may further include a semiconductor device such as a three-dimensional (3D) stacked DRAM device. The semiconductor device may include a transistor located on a substrate. The transistor may include, for example, a low-temperature processed select transistor. A dielectric layer including, for example, high-k dielectric material may be formed on the transistor. The semiconductor device may further include the capacitor described above in the dielectric layer and electrically coupled to the transistor. The capacitor may include, for example, a trench capacitor. In at least one embodiment, the capacitor may include a bottom capacitor plate connected to a first source/drain region of the transistor and having a rough upper surface with a root mean square (RMS) surface roughness of at least 1.14.

The semiconductor device may utilize the capacitor as information storage. The semiconductor device may include a very simple structure that allows the device to increase surface area (e.g., surface area of bottom capacitor plate of the capacitor). The semiconductor device may thereby significantly enhance the capacitance of the capacitor to provide a high performance.

In addition, a method of making the semiconductor device may utilize a simple (e.g., easy) and inexpensive process and may not require any additional masks or additional processes compared to a traditional method. In particular, the one or more embodiments may be fully compatible with a conventional process including a back end of line (BEOL) process.

One or more of the embodiments may include a method of making a semiconductor device such as a DRAM device. The method may include forming a capacitor having a bottom capacitor plate, a capacitor dielectric layer on the bottom capacitor plate, and an upper capacitor plate on the capacitor dielectric layer. The bottom capacitor plate and/or the upper capacitor plate may include a TiN layer. The rough upper surface of the bottom capacitor plate may include an upper surface of the TiN layer. In at least one embodiment, the bottom capacitor plate and/or the upper capacitor plate may be formed by atomic layer deposition (ALD). In at least one embodiment, the bottom capacitor plate and/or the upper capacitor plate may be formed by plasma enhanced atomic layer deposition (PEALD).

The capacitor may include a plurality of TiN layers having the same or different RMS surface roughness. In at least one embodiment, the bottom capacitor plate may include a first TiN layer having a first RMS surface roughness (e.g., at least 1.14) and the upper capacitor plate may include a second TiN layer having a second RMS surface roughness the same as or different than (e.g., greater than or less than) the first RMS surface roughness.

The TiN layer may be formed by PEALD to have a surface roughness that is greater, for example, than a surface roughness of a TiN layer formed by thermal atomic layer deposition (THALD) or physical vapor deposition (PVD). As a result, the TiN layer formed by PEALD may have a surface area that is greater than a surface area of the TiN layer formed by THALD or PVD. Thus, the capacitor having a bottom capacitor plate including the TiN layer formed by PEALD may have a capacitance that is greater than a capacitance of a capacitor including the TiN layer formed by THALD or PVD. In at least one embodiment, a capacitance of the capacitor including the TiN layer formed by PEALD may have a capacitance of 10.52fF or more compared to a capacitance of about 9.97fF or less where the TiN layer is formed by THALD.

One or more embodiments may include an embedded capacitor including a TiN layer formed by PEALD. In at least one embodiment, the bottom capacitor plate (e.g., rough electrode) of the embedded capacitor may include the TiN layer formed by PEALD. The embedded capacitor may be included, for example, in a 3D embedded transistor-capacitor structure of a semiconductor device (e.g., DRAM device).

One or more embodiments may be utilized, for example, in logic devices, memory devices, or any circuits needing large capacitance, for example DRAM, electrostatic discharge (ESD) devices, radio frequency (RF) devices, etc. One or more embodiments may be included, for example, in a BEOL transistor-capacitor such as in eDRAM, ESD devices, and RF devices.

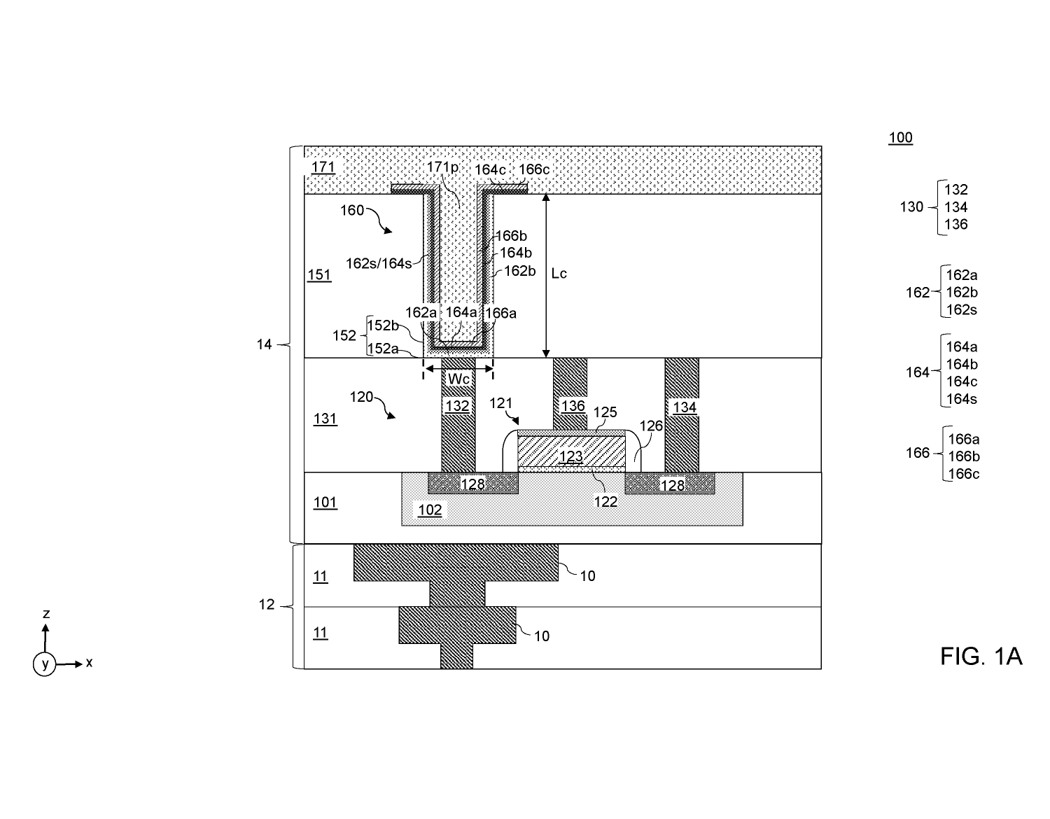

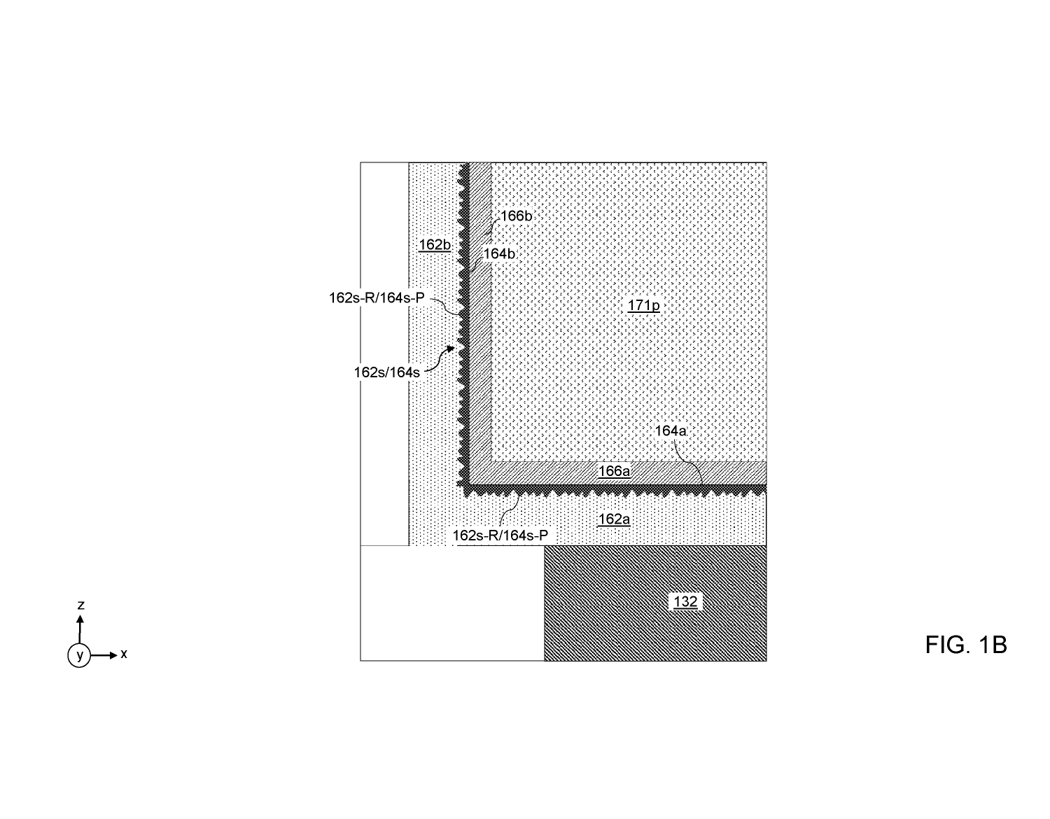

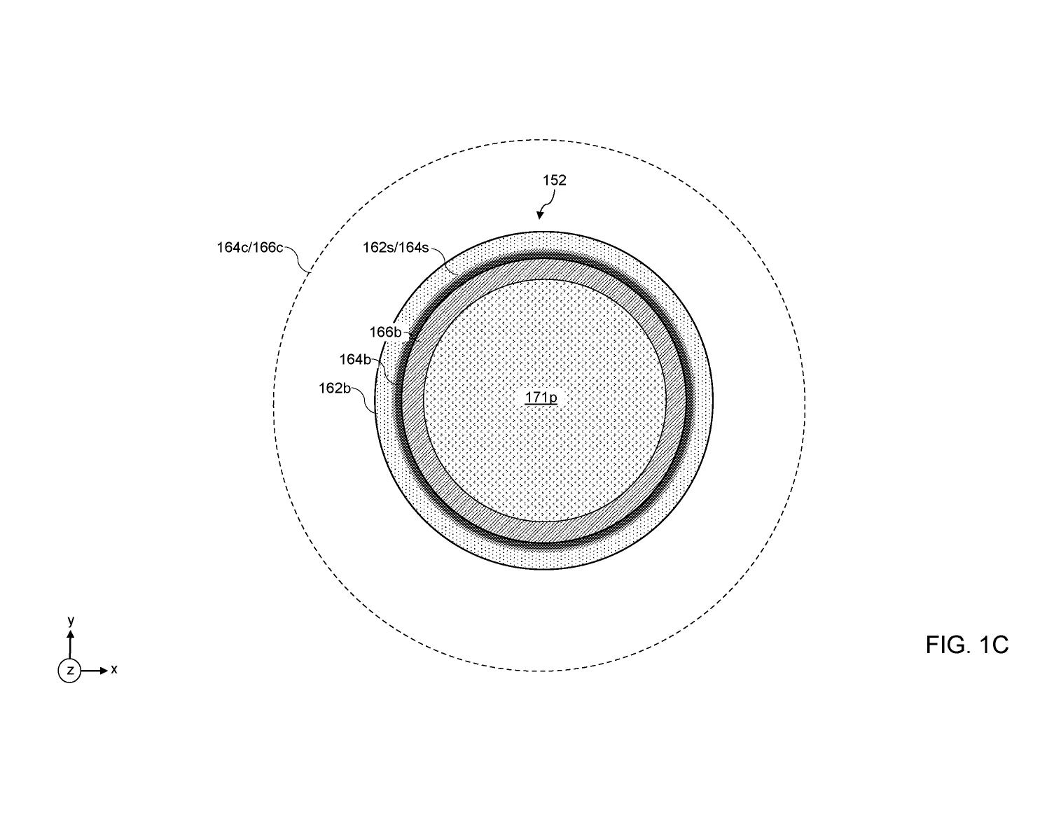

Referring to the drawings, FIG. 1A illustrates a vertical cross-sectional view of a semiconductor device 100 according to one or more embodiments. The semiconductor device 100 may include, for example, a transistor 120 and a capacitor 160 that together constitute a 1-transistor/1-capacitor (1T1C) memory cell or DRAM cell in a DRAM device. The transistor 120 and capacitor 160 may include BEOL devices formed in a BEOL process.

As illustrated in FIG. 1A, the semiconductor device 100 may include FEOL device circuitry 12 and BEOL device circuitry 14 on the FEOL device circuitry 12. The FEOL device circuitry 12 may be fabricated over and/or on a substrate (not shown) such as a semiconductor substrate e.g., (silicon wafer). The FEOL device circuitry 12 may include one or more transistors such as MOSFETs (not shown) in an active device area of the substrate. The semiconductor substrate may include any material known to be suitable for the fabrication of MOSFET circuitry, such as, but not limited to, group IV materials (e.g., substantially pure silicon, substantially pure germanium, and SiGe alloys that may range from predominantly Si to predominantly Ge).

The FEOL device circuitry 12 may further include one or more dielectric material layers 11 and one or more levels of interconnect metallization 10 formed in and electrically insulated by the dielectric material layers 11. The interconnect metallization 10 may include any metal(s) suitable for FEOL and/or BEOL integrated circuit interconnection. The interconnect metallization 10, may include, for example, an alloy of predominantly Cu, an alloy of predominantly W, or an alloy of predominantly Al, etc. The dielectric material layers 11 may include any dielectric material known to be suitable for electrical isolation of monolithic ICs. In some embodiments, the dielectric material layers 11 may include silicon, and at least one of oxygen and nitrogen. The dielectric material layers 11 may include, for example, SiO, SiN, or SiON. The dielectric material layers 11 may also be a low-K dielectric material (e.g., having a dielectric constant below that of SiO₂).

As further illustrated in FIG. 1A, the BEOL device circuitry 14 may include the transistor 120 and the capacitor 160 of a DRAM cell. The BEOL device circuitry 12 may include any number of metallization levels over the FEOL circuitry 12. The transistor 120 may be located in a dielectric layer 101. The dielectric layer 101 may include a material that is substantially similar to the material of the dielectric material layers 11 in the FEOL device circuitry 12. It should be noted that the DRAM cell may alternatively be located in the FEOL device circuitry 12 instead of the BEOL device circuitry 14.

The transistor 120 may include a field effect transistor such as a MOSFET. In at least one embodiment, the transistor may include a low-temperature processed select transistor for a DRAM cell. The transistor 120 may be formed on a layer of crystalline semiconductor material layer 102 (e.g., semiconductor substrate or substrate) in the dielectric layer 101. The semiconductor material layer 102 may include at least a channel region of the transistor 120. The semiconductor material layer 102 may have a microstructure associated with that of a seed structure (not shown) in the dielectric layer 101.

The semiconductor material layer 102 may include a p-type, n-type, or intrinsic semiconductor material. The semiconductor material layer 102 may include a group IV semiconductor material such as silicon (Si), germanium (Ge), and alloys such as SiGe, GeSn, and SiGeSn. The semiconductor material layer 102 may have a melt temperature of at least 50°C. A localized/rapid thermal technique may be employed to generate a very high thermal gradient between the semiconductor material layer 102 and underlying materials so as to crystallize the semiconductor material of the semiconductor material layer 102 with minimal impact to the FEOL circuitry 12 or interconnect metallization 10. A thickness of the semiconductor material layer 102 may vary, but in one or more embodiments may be less than 50 nm, and advantageously less than 30 nm (e.g., in a range from 5nm to 25nm).

The transistor 120 may include a gate structure 121 on the semiconductor material layer 102 and a pair of source/drain regions 128 in the semiconductor material layer 102 adjacent the gate structure 121 (e.g., on opposing sides of the gate structure 121). The gate structure 121 may include a gate insulation layer 122 (e.g., gate oxide layer) on a surface of the semiconductor material layer 102. The gate insulating layer 122 may include one or more metal oxides such as Al₂O3, HfO₂, MgOx, and LaOx) and/or mixed-metal oxides (e.g., HfAlOx). The gate insulation layer 122 may additionally or alternatively include a thermal oxide layer. The gate insulation layer 122 may have a thickness in a range from about 50Å to 100Å.

The gate structure 121 may further include a gate electrode 123 on the gate insulation layer 122. The gate electrode 123 may include a conductive material such as polysilicon, a silicide material, a metal material or a metal composite material. The gate electrode 123 may also include alloy constituents such as C, Ta, W, Pt, and Sn. The gate electrode 123 may include a metal nitride (e.g., WN, TiN, or TaN) and may also include Al (e.g., TiAlN). In at least one embodiment the gate electrode 123 may include a doped polysilicon layer (e.g., doped with arsenic, phosphorus, etc.). Other suitable conductive materials are within the contemplated scope of disclosure. The gate electrode 123 may have a thickness in a range from about 500 Å to 2000 Å.

The gate structure 121 may further include a silicide layer 124 on the gate electrode 123. The silicide layer 124 may include a refractory metal silicide (e.g., tungsten silicide). The silicide layer 124 may also have a thickness in a range from about 500 Å to 2000 Å. The gate structure 121 may also include sidewall spacers 126 on a sidewall of the gate electrode 123 and a sidewall of the silicide layer 124. The sidewall spacers 126 may include, for example, one or more layers of silicon oxide (e.g., SiO₂) and/or silicon nitride (e.g., Si₃N₄), silicon oxynitride, or any known low-k material. Other suitable materials are within the contemplated scope of disclosure.

The transistor 120 may further include source/drain regions 128 in the semiconductor material layer 102. In the case where the semiconductor material layer 102 includes a p-type substrate, the source/drain regions 128 may include n-type source/drain regions. The source/drain regions 128 may be doped, for example, with dopant ions such as arsenic, phosphorus, etc. The source/drain regions 128 may include lightly-doped extension regions (not shown) adjacent the gate structure 121 and under the sidewall spacers 126. A silicide layer (not shown) may be formed on an upper surface of the source/drain regions 128 to reduce contact resistance.

The semiconductor device 100 may further include a first dielectric layer 131 located on the semiconductor material layer 102 and over the gate structure 121. The first dielectric layer 131 may include a material that is substantially similar to the material of the dielectric material layers 11 in the FEOL device circuitry 12. In at least one embodiment, the first dielectric layer 131 may include interlayer dielectric (ILD) and may be formed of a dielectric material such as silicon dioxide (SiO₂). Other suitable dielectric materials are within the contemplated scope of disclosure. The first dielectric layer 131 may have a thickness in a range from 3nm to 20nm.

The semiconductor device 100 may also include contact metallization 130 which may provide for electrically coupling the transistor 120. The contact metallization 130 may include a first source/drain contact 132, second source/drain contact 134 and gate electrode contact 136. The first source/drain contact 132 may be connected to a source/drain region 128. The second source-drain contact 134 may be connected to the other source/drain region 128. The gate electrode contact 136 may be connected to the gate electrode 123 through the silicide layer 125. In at least one embodiment, the first source/drain contact 132 may be connected to a source of the source/drain regions 128 and the second source-drain contact 134 may be connected to a drain of the source/drain regions 128. In at least one embodiment, the second source-drain contact 134 may connect the drain of the source/drain regions 128 to a bit line (not shown) of a DRAM device, and the gate electrode contact 136 may connect the gate electrode 123 to a word line (not shown) of the DRAM device.

The contact metallization 130 may have any composition known to provide a suitable contact to semiconductor materials. The contact metallization 130 may form a Schottky or ohmic junction with the source/drain semiconductor material of the source/drain regions 128. The contact metallization 130 may include, for example, one or more metals or metallic compounds. In some embodiments, the contact metallization 130 may include a metal nitride at the interface of (i.e., in direct contact with) the source/drain regions 128. The metal nitride may include TiN, TaN, and WN. The contact metallization 130 may also, or in the alternative, include a noble metal (e.g., Pt) at the interface of (i.e., in direct contact with) source/drain regions 128. Other suitable metal materials are within the contemplated scope of disclosure.

The semiconductor device 100 may further include a second dielectric layer 151 located on the first dielectric layer 131. An etching stop layer (not shown) such as silicon carbide, silicon nitride, or the like may be located on the first dielectric layer 131, in which case the second dielectric layer 151 may be located on the etching stop layer. The second dielectric layer 151 may include a material that is substantially similar to the material of the dielectric material layers 11 in the FEOL device circuitry 12. The second dielectric layer 151 (e.g., ILD layer) may be formed of a dielectric material such as silicon oxide. Other suitable dielectric materials are within the contemplated scope of disclosure. The second dielectric layer 151 may have a thickness in a range from 50nm to 2500nm.

The second dielectric layer 151 may include a trench 152 extending substantially perpendicular (e.g., in the z-direction) to the surface of the semiconductor material layer 102. The trench 152 may have a substantially circular cylindrical shape extending axially perpendicular to the surface of the semiconductor material layer 102. The depth (e.g., in the z-direction) of the trench 152 may be in a range from 50nm to 2500nm. The trench 152 may extend over an entire thickness of the second dielectric layer 151. That is, a depth of the trench 152 may be substantially equal to the thickness of the second dielectric layer 151. A width (e.g., diameter) of the trench 152 may be in a range from 20nm to 200 nm.

The trench 152 may have a trench bottom 152a that is constituted in part by an upper surface of the first dielectric layer 131 and in part by an upper surface of the first source/drain contact 132. The trench bottom 152a may have a substantially circular shape. As illustrated in FIG. 1A, the width of the trench 152 (and thus a width of the trench bottom 152a) may be greater than a width of the first source/drain contact 132. The trench 152 may also include a trench sidewall 152b extending substantially perpendicularly from from the trench bottom 152a. A length (e.g., in the z-direction) of the trench sidewall 152b may be substantially equal to the depth of the trench 152.

The capacitor 160 may be located in the trench 152. The capacitor 160 may include a bottom capacitor plate 162, a capacitor dielectric layer 164 on the bottom capacitor plate 162 and an upper capacitor plate 166 on the capacitor dielectric layer 164. The capacitor 160 may substantially fill the trench 152 and may, therefore, have a size and shape substantially similar to the size and shape of the trench 152. In particular, the capacitor 160 may have a substantially circular cylindrical shape extending axially perpendicular to the surface of the semiconductor material layer 102.

A length Lc of the capacitor 160 may be in a range from 50nm to 2500nm and substantially equal to the thickness of the second dielectric layer 151. A width Wc (e.g., diameter) of the capacitor 160 may be in a range from 20nm to 200 nm. In at least one embodiment, the capacitor 160 may have a capacitance of at least 10.52fF. In at least one embodiment, the capacitor 160 may serve as an information storage element in a DRAM cell.

The bottom capacitor plate 162 may include a bottom capacitor plate bottom portion 162a and a bottom capacitor plate sidewall portion 162b extending substantially perpendicular to the bottom capacitor plate bottom portion 162a. The bottom capacitor plate 162 may have a substantially uniform thickness throughout the bottom capacitor plate bottom portion 162a and bottom capacitor plate sidewall portion 162b. In at least one embodiment, the thickness of the bottom capacitor plate 162 may be in a range from 2nm to 150nm. The bottom capacitor plate bottom portion 162a may located on the trench bottom 152a and the bottom capacitor plate sidewall portion 162b may be located on the trench sidewall 152b.

The bottom capacitor plate bottom portion 162a may contact the upper surface of the first source/drain contact 132. In at least one embodiment, an inner portion (e.g., inner diameter portion) of the bottom capacitor plate bottom portion 162a may contact the upper surface of the first source/drain contact 132 and an outer portion (e.g., outer diameter portion) of the bottom capacitor plate bottom portion 162a may contact the upper surface of the second dielectric layer 151.

It should be noted that it one or more embodiments, the bottom capacitor plate bottom portion 162a may not necessarily contact the upper surface of the first source/drain contact 132. There may be one or more intervening dielectric layers (e.g., intermetal dielectric (IMD) layers) between the first dielectric layer 131 and the second dielectric layer 151. In that case, the bottom capacitor plate bottom portion 162a may be electrically coupled to the upper surface of the first source/drain contact 132 by one or more metal layers in the one or more intervening dielectric layers.

In at least one embodiment, a centerpoint of the bottom capacitor plate bottom portion 162a may be substantially aligned with a centerpoint of the upper surface of the first source/drain contact 132. That is, the bottom capacitor plate bottom portion 162a and the upper surface of the first source/drain contact 132 may be concentrically arranged. In at least one embodiment, the first source/drain contact 132 may be connected to a source of the source/drain regions 128 and the bottom capacitor plate 162 is electrically coupled to the source through the first source/drain contact 132.

The bottom capacitor plate 162 may be formed of one or more layers of conductive material such as a metal or metal alloy. The conductive material may include, for example, Al, Ta, Ag, Cu, W, Co, Pd, Pt, Ni, Nb, other low resistivity metal constituent, an alloy thereof, or a combination thereof. In at least one embodiment, the bottom capacitor plate 162 may include a layer of TiN. Other suitable metal materials are within the contemplated scope of disclosure. The bottom capacitor plate 162 may also include a rough upper surface 162s. In at least one embodiment, the bottom capacitor plate 162 may include a layer of TiN and the rough upper surface 162s may include an upper surface of the layer of TiN. In at least one embodiment, the rough upper surface may have a root mean square (RMS) surface roughness of at least 1.14.

The capacitor dielectric layer 164 may include a capacitor dielectric layer bottom portion 164a and a capacitor dielectric layer sidewall portion 164b extending substantially perpendicular to the capacitor dielectric layer bottom portion 164a. The capacitor dielectric layer 164 may also include a capacitor dielectric layer upper portion 164c located on an upper surface of the second dielectric layer 151 outside the trench 152. The capacitor dielectric layer upper portion 164c may also be formed on an end of the bottom capacitor plate sidewall portion 162b. A length of the capacitor dielectric layer upper portion 164c (in the x-direction) may be at least three times the thickness of the bottom capacitor plate 162.

The capacitor dielectric layer 164 may have a substantially uniform thickness throughout the capacitor dielectric layer bottom portion 164a, capacitor dielectric layer sidewall portion 164b and capacitor dielectric layer upper portion 164c. The thickness of the capacitor dielectric layer 164 may be less than the thickness of the bottom capacitor plate 162. In at least one embodiment, the thickness of the capacitor dielectric layer 164 may be in a range from 2nm to 20nm. The capacitor dielectric layer bottom portion 164a may be located on the bottom capacitor plate bottom portion 162a and the capacitor dielectric layer sidewall portion 164b may be located on the bottom capacitor plate sidewall portion 162b.

The capacitor dielectric layer 164 may be formed of one or more layers of dielectric material (e.g., low-k dielectric material, high-k dielectric material, etc.). The dielectric material may include, for example, hafnium silicate, zirconium silicate, hafnium dioxide, zirconium dioxide, etc. Other suitable metal materials are within the contemplated scope of disclosure. The capacitor dielectric layer 164 may also include a lower surface 164s which may contact the rough upper surface 162s of the bottom capacitor plate 162. The lower surface 164s of the capacitor dielectric layer 164 may be located on the capacitor dielectric layer bottom portion 164a and the capacitor dielectric layer sidewall portion 164b.

The upper capacitor plate 166 may include an upper capacitor plate bottom portion 166a and an upper capacitor plate sidewall portion 166b extending substantially perpendicular to the upper capacitor plate bottom portion 164a. The upper capacitor plate 166 may also include an upper capacitor plate upper portion 166c located on the capacitor dielectric layer upper portion 164c outside the trench 152. An end of the upper capacitor plate upper portion 166c may have an end that is substantially aligned with an end of the capacitor dielectric layer upper portion 164c. A length of the upper capacitor plate upper portion 166c (in the x-direction) may be substantially the same as a length of the capacitor dielectric layer upper portion 164c.

The upper capacitor plate 166 may have a substantially uniform thickness throughout the upper capacitor plate bottom portion 166a, upper capacitor plate sidewall portion 164b and upper capacitor plate upper portion 166c. In at least one embodiment, the thickness of the upper capacitor plate 166 may have vary among the upper capacitor plate bottom portion 166a, upper capacitor plate sidewall portion 164b and upper capacitor plate upper portion 166c. For example, a thickness of the upper capacitor plate bottom portion 166a may be different than (e.g., greater than or less than) a thickness of the upper capacitor plate sidewall portion 164b and/or a thickness of the upper capacitor plate upper portion 166c, a thickness of the upper capacitor plate sidewall portion 164b may be different than a thickness of the upper capacitor plate bottom portion 166a and/or a thickness of the upper capacitor plate upper portion 166c, and a thickness of the upper capacitor plate upper portion 166c may be different than a thickness of the upper capacitor plate bottom portion 166a and/or a thickness of the upper capacitor plate sidewall portion 164b.

In at least one embodiment, the thickness of the upper capacitor plate 166 may be substantially the same as the thickness of the bottom capacitor plate 162. In at least one embodiment, the thickness of the upper capacitor plate 166 may be greater than the thickness of the capacitor dielectric layer 164 and less than the thickness of the bottom capacitor plate 162. In at least one embodiment, the thickness of the upper capacitor plate 166 may be in a range from 2nm to 150nm. The upper capacitor plate bottom portion 166a may be located on the capacitor dielectric layer bottom portion 164a and the upper capacitor plate sidewall portion 166b may be located on the capacitor dielectric layer sidewall portion 164b.

The upper capacitor plate 166 may be formed of one or more layers of conductive material such as a metal or metal alloy. The conductive material may include, for example, Al, Ta, Ag, Cu, W, Co, Pd, Pt, Ni, Nb, other low resistivity metal constituent, an alloy thereof, or a combination thereof. In at least one embodiment, the upper capacitor plate 166 may be formed of substantially the same material as the bottom capacitor plate 162. In at least one embodiment, the upper capacitor plate 166 may include a layer of TiN. Other suitable metal materials are within the contemplated scope of disclosure.

The capacitor 160 may include a plurality of TiN layers having the same or different RMS surface roughness. In at least one embodiment, the bottom capacitor plate 162 may include a first TiN layer having a first RMS surface roughness (e.g., at least 1.14) and the upper capacitor plate 166 may include a second TiN layer having a second RMS surface roughness the same as or different than (e.g., greater than or less than) the first RMS surface roughness.

The semiconductor device 100 may further include a third dielectric layer 171 located on the second dielectric layer 151. The third dielectric layer 171 may include a material that is substantially similar to the material of the dielectric material layers 11 in the FEOL device circuitry 12. The third dielectric layer 171 (e.g., ILD layer) may be formed of a dielectric material such as silicon oxide. Other suitable dielectric materials are within the contemplated scope of disclosure. The third dielectric layer 171 may have a thickness in a range from 50nm to 2500nm.

The third dielectric layer 171 may include a third dielectric layer projecting portion 171p that projects downwardly into the capacitor 160. In particular, a recess may be located in a central portion of the capacitor 160 on the upper capacitor plate 166. The third dielectric layer projecting portion 171p may project onto the upper capacitor plate 166 in the central portion of the capacitor 160 and fill the recess.

FIG. 1B is a detailed vertical cross-sectional view of a lower corner region of the capacitor 160 according to one or more embodiments. As illustrated in FIG. 1B, the capacitor 160 may include an interface between the rough upper surface 162s of the bottom capacitor plate 162 and the lower surface 164s of the capacitor dielectric layer 164. The interface may have an interdigitated design in which a plurality of projections 164s-P of the lower surface 164s of the capacitor dielectric layer 164 project into a recessed portion 162s-R of the rough upper surface 162s of the bottom capacitor plate 162, respectively. The recessed portion 162s-R may include one or more recesses in the rough upper surface 162s (e.g., a plurality of recesses). The interface may be located over substantially the entire rough upper surface 162s of the bottom capacitor plate 162.

As illustrated in FIG. 1B, the recessed portion 162s-R (as well as the plurality of projections 164s-P) may have an irregular configuration. That is, the recesses in the recessed portion 162s-R may have varying depths and widths. The spaces between the recesses may also vary.

Further, in at least one embodiment, a thickness of the capacitor dielectric layer 164 may be less than a depth of the recesses 162s-R and, therefore, not fill the recesses 162s-R. In that case the upper capacitor plate 166 may also project into the one or more recesses of the recessed portion 164s-R. In addition, in at least one embodiment, a combined thickness of the capacitor dielectric layer 164 and the upper capacitor plate 166 may be less than a depth of the recesses 162s-R and not fill the recesses 162s-R. In that case the third dielectric layer projecting portion 171p may project into the one or more recesses of the recessed portion 164s-R onto the upper capacitor plate 166.

FIG. 1C is a horizontal cross-sectional view of the capacitor 160 according to one or more embodiments. A location of the ends (e.g., coextensive ends) of the capacitor dielectric layer upper portion 164c and the upper capacitor plate upper portion 166c is indicated by a dashed line in FIG. 1C for ease of understanding.

As illustrated in FIG. 1C, the trench 152 may be filled with elements of the capacitor 160. In at least one embodiment, the third dielectric layer projecting portion 171p, the upper capacitor plate sidewall portion 166b, the capacitor dielectric layer sidewall portion 164b and the bottom capacitor plate sidewall portion 162b may all be concentrically formed. The ends of the capacitor dielectric layer upper portion 164c and upper capacitor plate upper portion 166c may also be concentrically formed with the trench 152 and the elements of the capacitor 160 inside the trench 152.

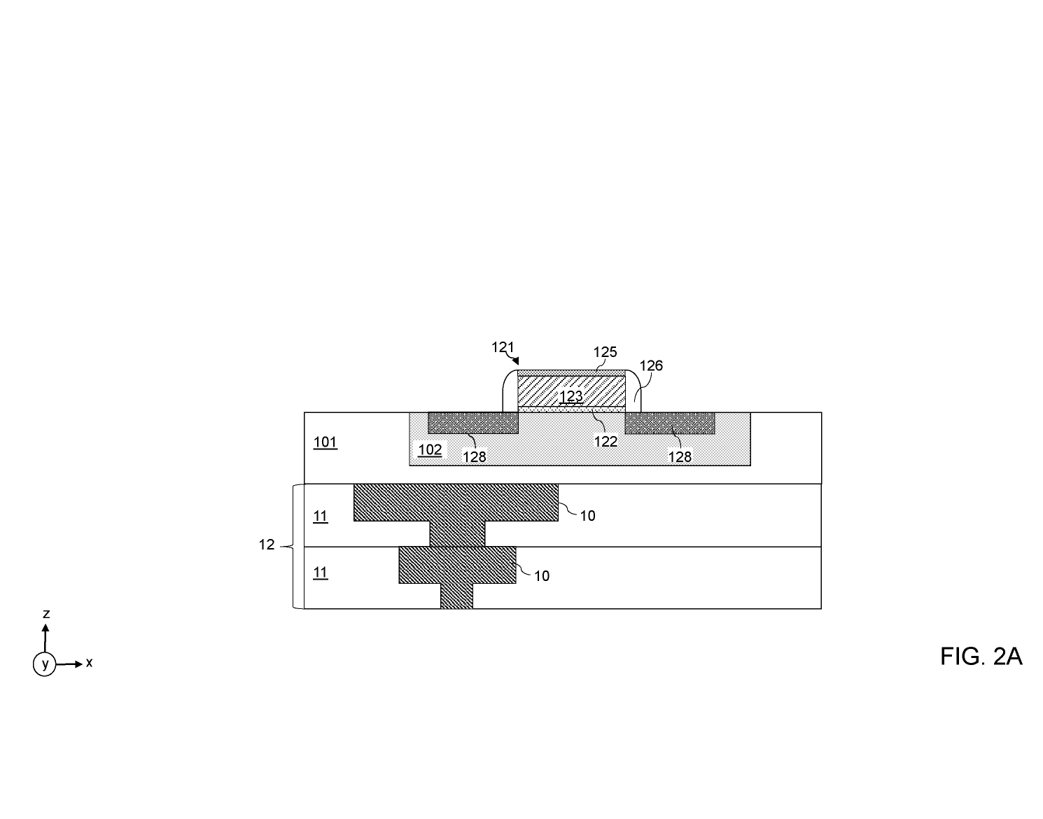

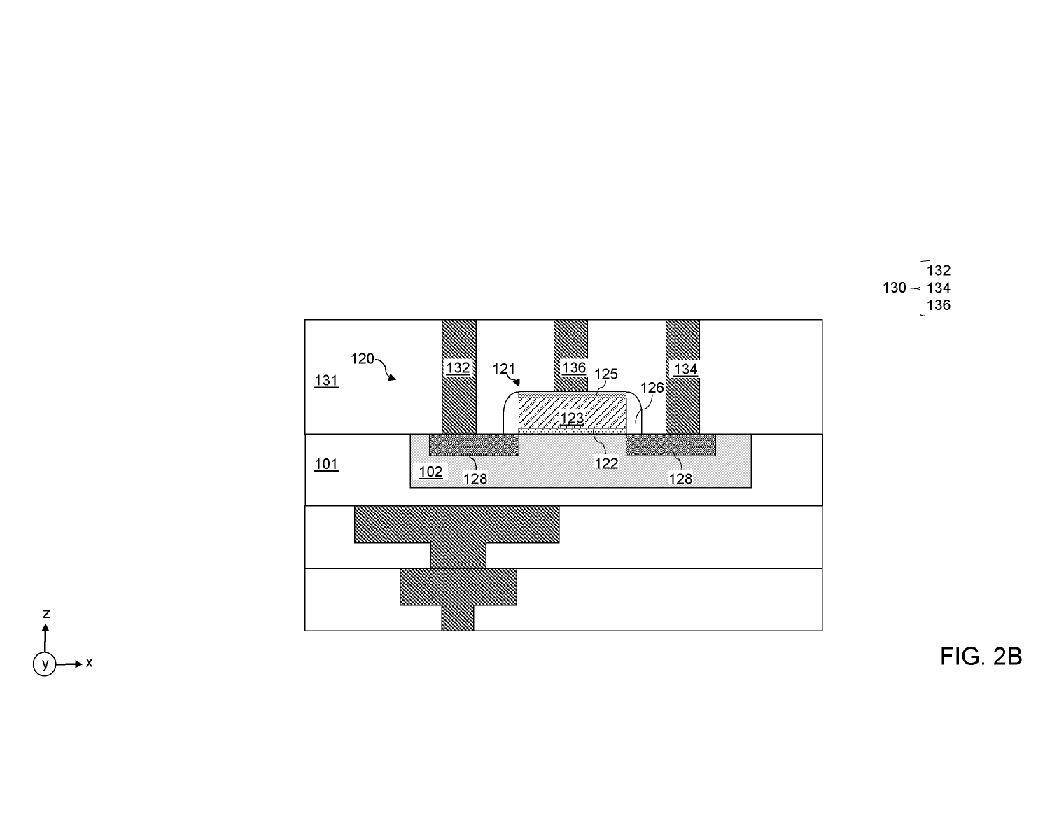

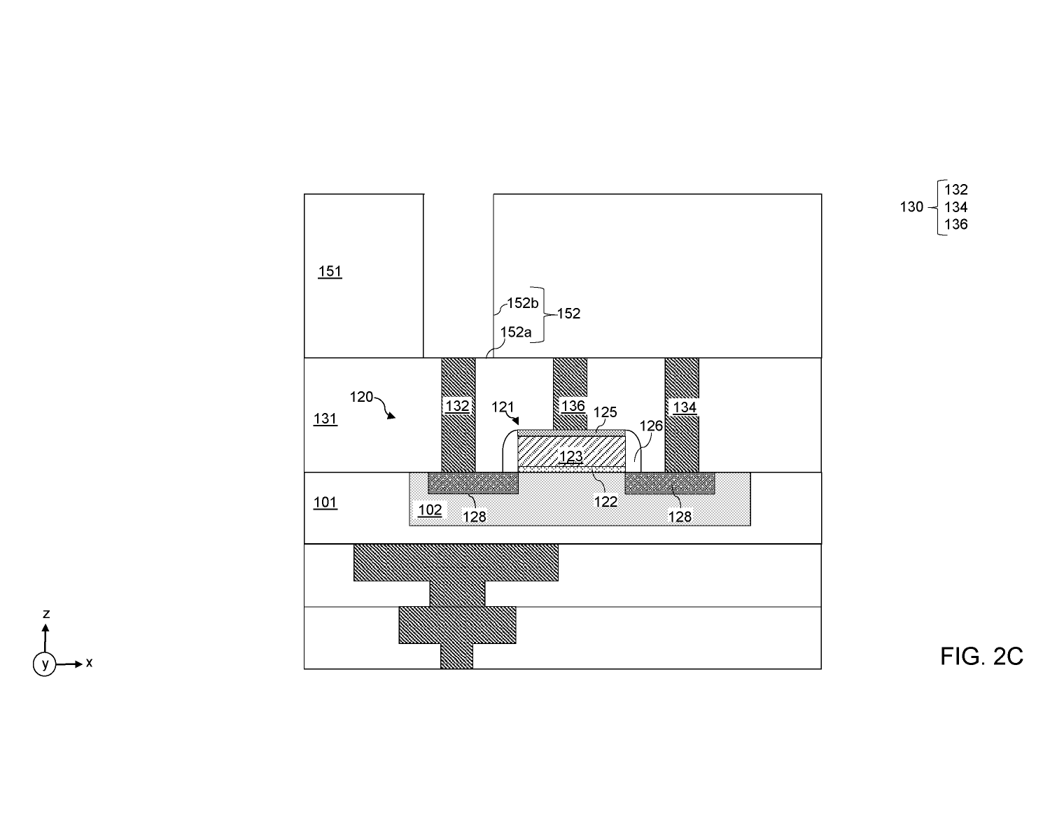

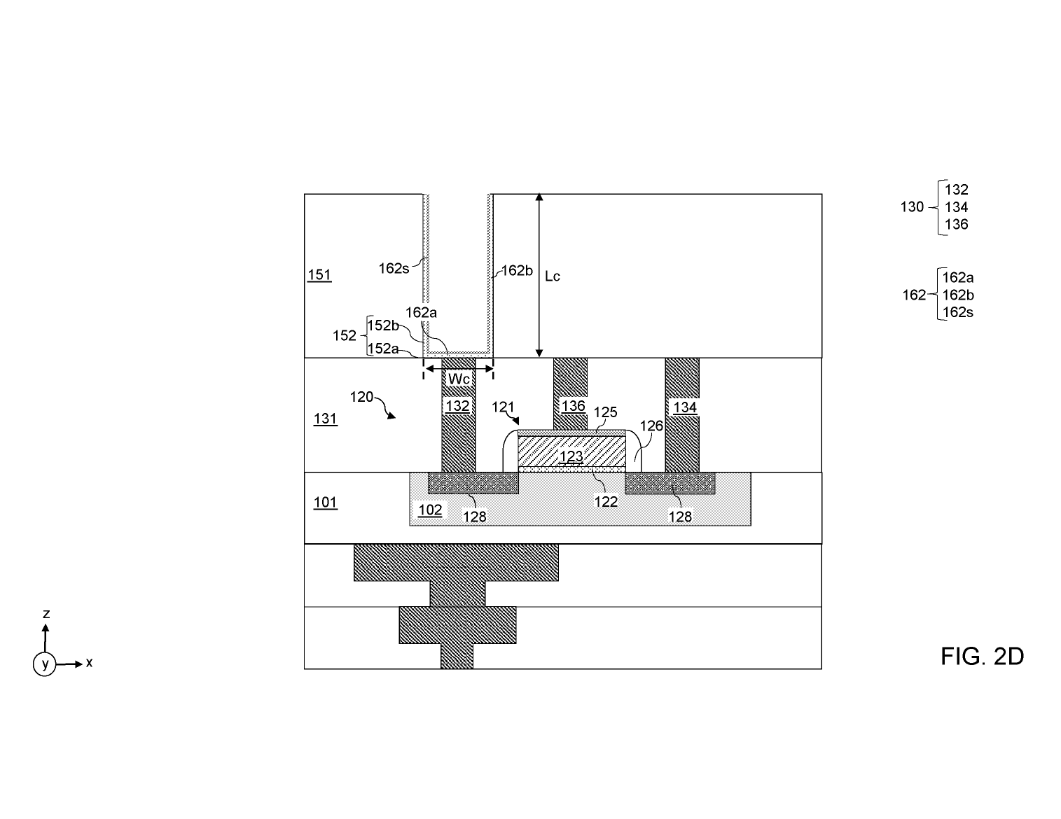

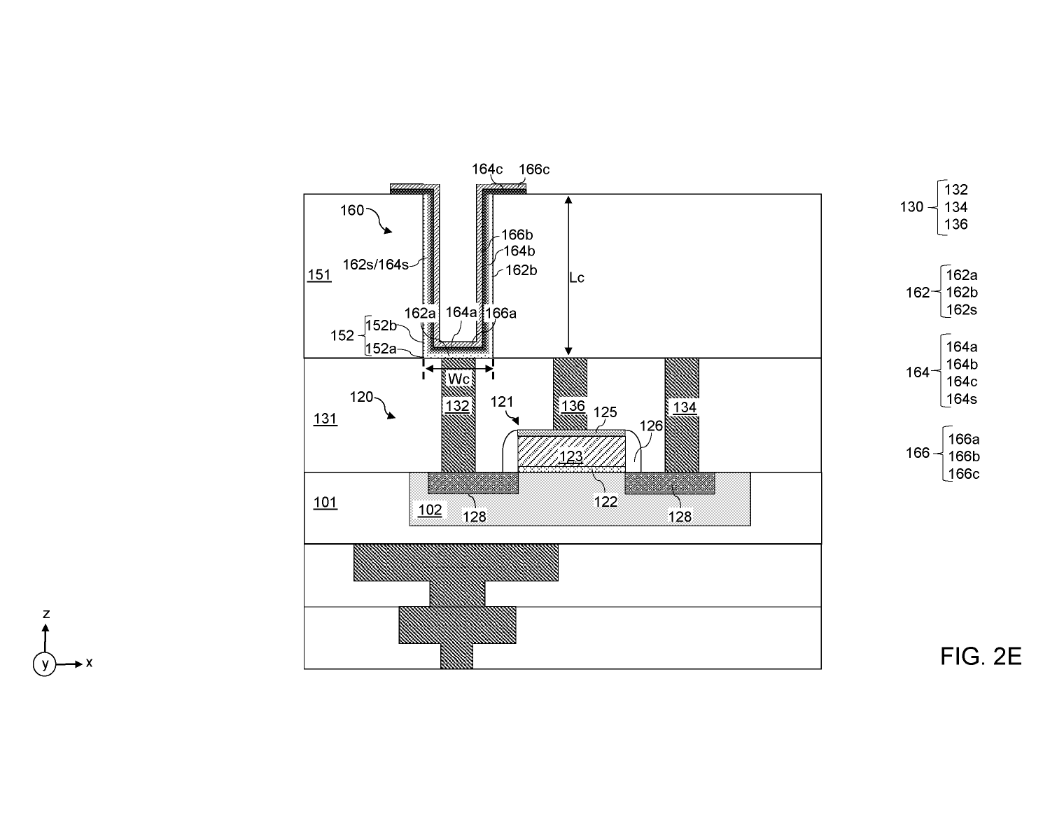

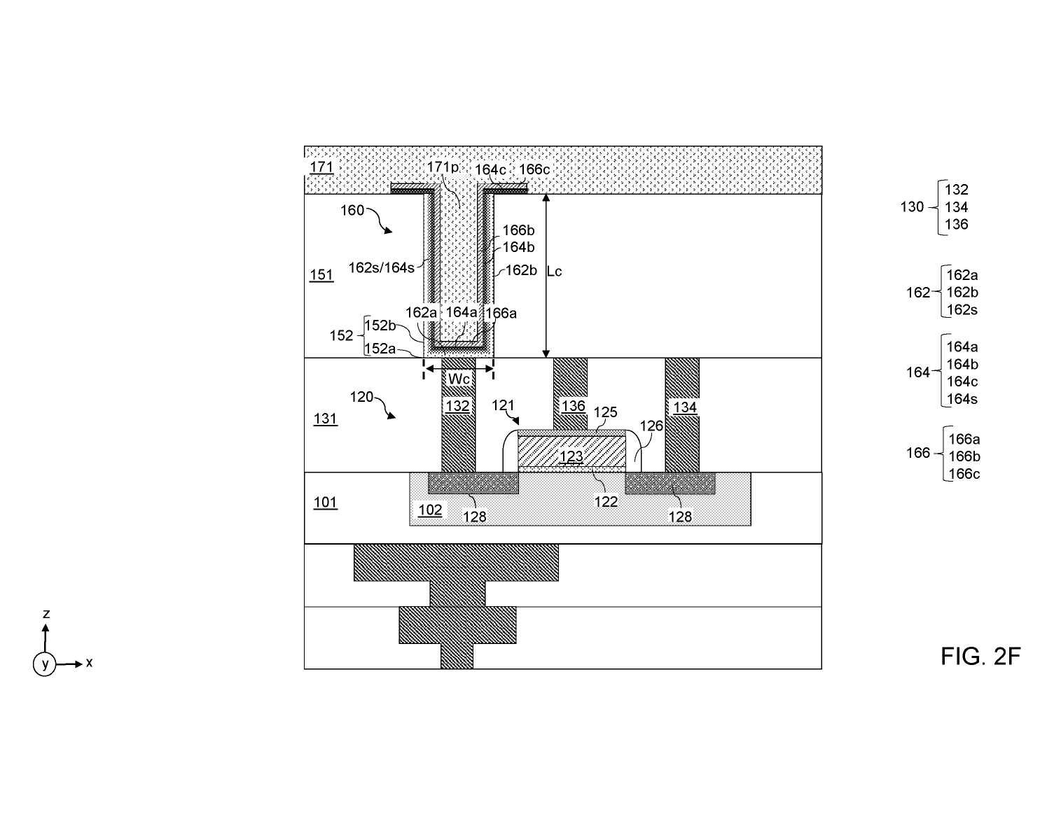

FIGS. 2A-2I illustrate sequential operations of a method of forming a semiconductor device (e.g., DRAM memory cell), according to one or more embodiments. The method illustrated in FIGS. 2A-2I may depict the forming of one memory cell including the transistor 120 and capacitor 160. However, the method is not limited to such a configuration. Embodiment methods described herein may be used to form (e.g., simultaneously form) any number of DRAM memory cells.

FIG. 2A is an intermediate structure after formation of the gate structure 121 and source/drain regions 128, according to one or more embodiments. The FEOL device circuitry 12 including the interconnect metallization 10 in the dielectric material layers 11 may be provided.

The dielectric layer 101 may be formed on the dielectric material layers 11 of the FEOL device circuitry 12. The dielectric layer 101 may be formed, for example, by depositing a layer of dielectric material (e.g., SiO₂) on the dielectric material layers 11. The dielectric material may be deposited by chemical vapor deposition (CVD), PVD or other suitable deposition method. In at least one embodiment, the layer of dielectric material may include a layer of SiO₂ deposited by low-pressure chemical vapor deposition (LPCVD) using tetraethosiloxane (TEOS) as the reactant gas. The layer of dielectric material may be deposited to a thickness in a range from 3000 Å to 8000 Å. An upper surface of the dielectric layer 101 may then be planarized by performing, for example, chemical/mechanical polishing (CMP) using an appropriate polishing slurry.

The semiconductor material layer 102 (e.g., semiconductor substrate, silicon wafer, SOI substrate, doped semiconductor substrate, etc.) may be formed in the dielectric layer 101. The semiconductor material layer 102 may be formed, for example, by forming a BEOL crystalline seed over the dielectric layer 101 which may be located over the FEOL device circuitry 12 which employs a monocrystalline substrate semiconductor. The BEOL crystalline seed may be epitaxial to the monocrystalline substrate semiconductor, or may have crystallinity independent of that of the monocrystalline substrate semiconductor. The BEOL crystalline seed may include a first material having a higher melt temperature than a melt material formed over the BEOL crystalline seed and over the dielectric layer 101. Through rapid melt growth, the melt material may be heated to a temperature sufficient to transition from an as-deposited state to a crystallized material that is derived from, and therefore associated with, the BEOL crystalline seed. The semiconductor material layer 102 may be constituted of the crystallized material.

The gate structure 121 and source/drain regions 128 may then be formed on the semiconductor material layer 102. First, an insulating layer (e.g., corresponding to the gate insulating layer 122) may be formed on the semiconductor material layer 102. The insulating layer may be formed, for example, by depositing an insulating material such as one or more metal oxides such as Al₂O3, HfO₂, MgOx, and LaOx) and/or mixed-metal oxides (e.g., HfAlOx), or by thermally oxidizing the semiconductor material layer 102. The insulating material may be deposited by CVD, PVD or other suitable deposition technique. The insulating layer may be formed to have a thickness in a range from 50Å to 100Å. Other suitable methods of forming the insulating layer are within the contemplated scope of disclosure.

An appropriately doped polysilicon layer (e.g., corresponding to the gate electrode 123) may then be deposited on the insulating layer. The polysilicon layer may be deposited by CVD, PVD or other suitable deposition method. In at least one embodiment, the polysilicon layer may be deposited by LPCVD to a thickness in a range from 500 Å to 2000 Å. The polysilicon layer may then be appropriately doped by an ion implantation process. In at least one embodiment, arsenic or phosphorus may be implanted where the transistor 120 includes an N-channel FET.

A silicide layer (e.g., corresponding to the silicide layer 125) may then be formed on the doped polysilicon layer. In at least one embodiment, the silicide layer may include tungsten silicide (WSi₂). The silicide layer may be formed, for example, by reacting a surface of the polysilicon layer with tungsten hexafluoride (WF₆) (e.g., deposited by chemical vapor deposition (CVD)) in the presence of silane (SiH₄). the silicide layer may be formed to have a thickness in a range from 500 Å to 2000 Å.

A photolithographic process may then be performed to pattern the insulating layer, polysilicon layer and silicide layer. The photolithographic process may include forming a patterned photoresist mask (not shown) on the silicide layer, and etching (e.g., wet etching, dry etching, etc.) the silicide layer, polysilicon layer and insulating layer through openings in the photoresist mask to form the silicide layer 125, the gate electrode 123 and the gate insulating layer 122, respectively. The photoresist mask may be subsequently removed by ashing, dissolving the photoresist mask or by consuming the photoresist mask during the etch process.

The source/drain regions 128 may be formed in the semiconductor material layer 102 adjacent the gate insulating layer 122. The source/drain regions 128 may be formed by performing another ion implantation process. The ion implantation process may include ion implanting dopant ions such as arsenic or phosphorus in the semiconductor material layer 102.

The sidewall spacers 126 may then be formed on the sidewalls of the gate insulating layer 122, the gate electrode 123 and the silicide layer 125. The sidewall spacers 126 may be formed, for example, by depositing one or more layers of oxide (e.g. silicon oxide), nitride (e.g., silicon nitride) and/or oxynitride (e.g., silicon oxynitride) on the semiconductor material layer 102. The layers of oxide, nitride and/or oxynitride may be deposited by CVD, PVD or other suitable deposition method. In at least one embodiment, the layers of oxide, nitride and/or oxynitride may be deposited by LPCVD. The layers of oxide, nitride and/or oxynitride may then be anisotropically etched in a reactive ion etcher (RIE) to complete the formation of the gate structure 121.

FIG. 2B is an intermediate structure after formation of the first source/drain contact 132, second source/drain contact 134 and gate electrode contact 136, according to one or more embodiments. The first dielectric layer 131 may be formed on the semiconductor material layer 102 and the gate structure 121. The first dielectric layer 131 may be formed, for example, by depositing a layer of dielectric material (e.g., SiO₂) on the dielectric layer 101. The layer of dielectric material may be deposited by CVD, PVD or other suitable deposition method. In at least one embodiment, the layer of dielectric material may include a layer of SiO₂ deposited by LPCVD using tetraethosiloxane (TEOS) as the reactant gas. The layer of dielectric material may be deposited to a thickness in a range from 3000 Å to 8000 Å. An upper surface of the first dielectric layer 131 may then be planarized by performing, for example, CMP using an appropriate polishing slurry.

Openings may then be formed in the first dielectric layer 131 in order to accommodate the contact metallization 130 including the first source/drain contact 132, second source/drain contact 134 and gate electrode contact 136. The openings may be formed, for example, by etching the first dielectric layer 131. The etching may be performed so as to expose an upper surface of the source/regions 128 and an upper surface of the silicide layer 125. In at least one embodiment, the openings may be etched in the first dielectric layer 131 by using a high-density-plasma (HDP) etcher and an etchant gas mixture that selectively etches the SiO₂ of the first dielectric layer 131 to form self-aligned contacts (SAC). This selective etching may be achieved, for example, using a fluorine-based etchant gas mixture.

A conductive layer may then be formed on the first dielectric layer 131 and in the openings in the first dielectric layer 131. The conductive layer may include, for example, a metal material, polysilicon, etc. and may fill the openings. In at least one embodiment, the conductive layer may include a metal material (e.g., metal, metal alloy, metal compounds, metal nitrides such as TiN, TaN, and WN, etc.) and may be formed by depositing the metal material on the first dielectric layer 131 by CVD, plasma-enhanced CVD (PECVD), LPCVD, PVD or ALD. The metal material may then be planarized such as by CMP in order to make an upper surface of the contact metallization 130 (e.g., first source/drain contact 132, second source/drain contact 134 and gate electrode contact 136) to be coplanar with an upper surface of the first dielectric layer 131.

FIG. 2C is an intermediate structure after formation of the second dielectric layer 151 and the trench 152, according to one or more embodiments. A process of forming the second dielectric layer 151 may be substantially similar to the process of forming the first dielectric layer 131.

The second dielectric layer 151 may be formed on the upper surface of the first dielectric layer 131 and the upper surface of the contact metallization 130. The second dielectric layer 151 may be formed, for example, by depositing a layer of dielectric material (e.g., SiO₂) on the first dielectric layer 131. The dielectric material may be deposited by CVD, PVD or other suitable deposition method. In at least one embodiment, the layer of dielectric material may include a layer of SiO₂ deposited by LPCVD using tetraethosiloxane (TEOS) as the reactant gas. The layer of dielectric material may be deposited to a thickness in a range from 50nm to 2500nm. An upper surface of the second dielectric layer 151 may then be planarized by performing, for example, CMP using an appropriate polishing slurry.

The trench 152 may then be formed in the second dielectric layer 151 in order to accommodate the capacitor 160. The trench 152 may be formed, for example, by etching the second dielectric layer 151. The etching may be performed so as to expose the upper surface of the first dielectric layer 131 and the upper surface of the contact metallization 130. In at least one embodiment, the second dielectric layer 151 may be etched until the upper surface of the first source/drain contact 132 and the upper surface of the first dielectric layer 131 are exposed. In at least one embodiment, the trench 152 may be etched in the second dielectric layer 151 by using a high-density-plasma (HDP) etcher and an etchant gas mixture that selectively etches the SiO₂ of the second dielectric layer 151.

The trench 152 may be formed so as to have a depth and width (e.g., diameter) that are substantially the same as the length Lc and width Wc of the capacitor 160, respectively. In particular, the trench 152 may be formed to have a depth in a range from 50nm to 2500nm and substantially equal to the thickness of the second dielectric layer 151. The trench 152 may be formed to have a width (e.g., diameter) in a range from 20nm to 200nm.

FIG. 2D is an intermediate structure after formation of the bottom capacitor plate 162, according to one or more embodiments. The bottom capacitor plate 162 may be formed by conformally forming (e.g., depositing) a conductive material on the second dielectric layer 151 and in the trench 152. The conductive material may conform to a surface of the trench bottom 152a and the trench sidewall 152b so to have a shape (e.g., a circular cylinder) that is substantially the same as the shape of the shape of the trench 152. The bottom capacitor plate 162 may be formed so as to form the bottom capacitor plate bottom portion 162a on the trench bottom 152a and to form the bottom capacitor plate sidewall portion 162b on the trench sidewall 152b. The bottom capacitor plate 162 may be formed so as to have a substantially uniform thickness in a range from 2nm to 150nm.

The bottom capacitor plate 162 may be formed so as to include the rough upper surface 162s on both the bottom capacitor plate bottom portion 162a and the bottom capacitor plate sidewall portion 162b. In at least one embodiment, the bottom capacitor plate 162 may be formed so that the rough upper surface 162s has a root mean square (RMS) surface roughness of at least 1.14 on both the bottom capacitor plate bottom portion 162a and the bottom capacitor plate sidewall portion 162b. In at least one embodiment, the bottom capacitor plate 162 may be formed so that the rough upper surface 162s has the recessed portion 162s-R on both the bottom capacitor plate bottom portion 162a and the bottom capacitor plate sidewall portion 162b.

The method of forming the bottom capacitor plate 162 may be selected so as to provide the bottom capacitor plate 162 with the rough upper surface 162s having the recessed portion 162s-R and an RMS roughness of at least 1.14. In at least one embodiment, no additional processing may be needed after the forming (e.g., depositing) of the conductive material to provide the bottom capacitor plate 162 with the rough upper surface 162s having the recessed portion 162s-R and an RMS roughness of at least 1.14. In at least one embodiment, the method may include CVD such as PECVD, HDP-CVD, thermal CVD, APCVD, etc. In at least one embodiment, the method may include ALD such as PEALD, thermal ALD, etc.

In at least one embodiment, the bottom capacitor plate 162 may be formed by PEALD to provide the rough upper surface 162s having the recessed portion 162s-R and an RMS roughness of at least 1.14. The PEALD method may utilize a low processing temperature (less than 250 °C) to form a TiN layer constituting the bottom capacitor plate 162.

The PEALD method of forming the TiN layer may use argon (99.999%) as a carrier gas and as a purging gas. In at least one embodiment, the steps (e.g., all steps) of the PEALD method may be performed in an ALD reaction chamber under vacuum at 250 °C. The TiN layer may include one or more thin TiN films grown directly onto the surface of the second dielectric layer 151, onto a surface of the trench bottom 152a and onto a surface of the trench sidewall 152b.

The PEALD method may use tetrakis (dimethylamido) titanium (IV) (99%) (TDMAT) as the titanium precursor. The TDMAT may be heated to 65°C to increase its vapor pressure. The TDMAT may be exposed to the chamber for at least 1000 milliseconds, followed by at least a 10 second purge under an argon-rich environment (e.g., at least 110 sccm argon). The ALD chamber may then be exposed to a NH₃:Ar plasma for at leaset 20 seconds, followed by at least a 10 second purge under at least 110 sccm argon. The NH₃:Ar may include, for example, a 300 W NH₃:Ar plasma (10 sccm:100 sccm, respectively). This may complete one cycle. The cycle may be repeated until the desired thickness (e.g., in a range from 2nm to 150nm) is reached.

An optional conditioning step may be used to condition the PEALD deposited TiN layer. The optional conditioning step may include a post-deposition hydrogen plasma treatment on the TiN layer. In this optional conditioning step, after the TiN layer is deposited, the intermediate structure may be maintained inside the ALD chamber at 250 °C and repeatedly exposed to 5 second intervals of hydrogen plasma (e.g., 300W hydrogen plasma) balanced in argon. This may be repeated at least 600 times for a total 50 minute exposure of the TiN layer to the hydrogen plasma.

The conditioning step may further alter the properties of TiN while maintaining the thermal budget at the low temperature of 250°C. The conditioning step may reduce surface oxygen contamination and carbon contamination in the TiN layer. The conditioning step may also greatly improve a metallic quality of the TiN layer. In particular, the conditioning step may reduce the resistivity of the TiN layer.

After the TiN layer is deposited, a photolithographic process may be used to remove the TiN layer from the upper surface of the second dielectric layer 151. The photolithographic process may include forming a patterned photoresist mask (not shown) on the second dielectric layer 151, and etching (e.g., wet etching, dry etching, etc.) the conductive material (e.g. TiN) through openings in the photoresist mask. The photoresist mask may be subsequently removed by ashing, dissolving the photoresist mask or by consuming the photoresist mask during the etch process. A CMP step may alternatively or additionally be used to remove the conductive material and planarize the upper surface of the second dielectric material 151 with an end of the bottom capacitor portion sidewall portion 162b.

FIG. 2E is an intermediate structure after formation of the capacitor dielectric layer 164 and the upper capacitor plate 166, according to one or more embodiments. The capacitor dielectric layer 164 may be formed by depositing a layer of dielectric material (e.g., hafnium silicate, zirconium silicate, hafnium dioxide, zirconium dioxide, etc.) on the upper surface of the second dielectric layer 151 and in the trench 152 on the rough upper surface 162s of the bottom capacitor plate 162. The layer of dielectric material may be conformally formed on the rough upper surface 162s of the bottom capacitor plate 162. In at least one embodiment, the layer of dielectric material may be formed so that the projections 164s-P of the surface 164s of the capacitor dielectric layer 164 are formed in the recesses 162s-R of the rough upper surface 162s of the bottom capacitor plate 162 (e.g., see FIG. 1B).

The layer of dielectric material for the capacitor dielectric layer 164 may be formed, for example, by depositing the layer on the second dielectric layer 151 and in the trench 152. The layer of dielectric material may be deposited by CVD, PVD or other suitable deposition method. The layer of dielectric material may be deposited to have a substantially uniform thickness in a range from 2nm to 20nm.

The upper capacitor plate 166 may be formed by depositing a layer of conductive material (e.g., TiN, a metal such as Al, Ta, Ag, Cu, W, Co, Pd, Pt, Ni, Nb, other low resistivity metal constituent, an alloy thereof, or a combination thereof) on the layer of dielectric material for the capacitor dielectric layer 164. The layer of conductive material may be deposited on the layer of dielectric material in the trench 152 and on the upper surface of the second dielectric layer 151. The layer of conductive material for the upper capacitor plate 166 may be conformally formed on the capacitor dielectric layer 164.

The layer of conductive material for the upper capacitor plate 166 may be deposited by CVD, PVD or other suitable deposition method. The layer of conductive material may be deposited to have a substantially uniform thickness in a range from 2nm to 150nm.

A photolithographic process may then be used to form the capacitor dielectric layer upper portion 164c and the upper capacitor plate upper portion 166c. The photolithographic process may include forming a patterned photoresist mask (not shown) on the second dielectric layer 151. The layer of dielectric material for the capacitor dielectric layer 164 and the conductive layer for the upper capacitor plate 166 may then be etched (e.g., by wet etching, dry etching, etc.) through openings in the photoresist mask. The photoresist mask may be subsequently removed by ashing, dissolving the photoresist mask or by consuming the photoresist mask during the etch process. A CMP step may alternatively or additionally be used to remove the dielectric material and conductive material.

FIG. 2F is an intermediate structure after formation of the third dielectric layer 171 according to one or more embodiments. A process of forming the third dielectric layer 171 may be substantially similar to the process of forming the second dielectric layer 151.

The third dielectric layer 171 may be formed on the upper surface of the second dielectric layer 151 and on the upper capacitor plate 166 in the trench 152. The third dielectric layer 171 may be formed, for example, by depositing a layer of dielectric material (e.g., SiO2) on the second dielectric layer 151. The layer of dielectric material may be deposited so as to form the third dielectric layer projecting portion 171p on the upper capacitor plate 166. In at least one embodiment, the layer of dielectric material may fill the space remaining in the trench 152 over the upper capacitor plate 166.

The layer of dielectric material may be deposited by CVD, PVD or other suitable deposition method. In at least one embodiment, the layer of dielectric material may include a layer of SiO2 deposited by LPCVD using tetraethosiloxane (TEOS) as the reactant gas. The layer of dielectric material may be deposited to a thickness in a range from 50nm to 2500nm. An upper surface of the third dielectric layer 171 may then be planarized by performing, for example, CMP using an appropriate polishing slurry.

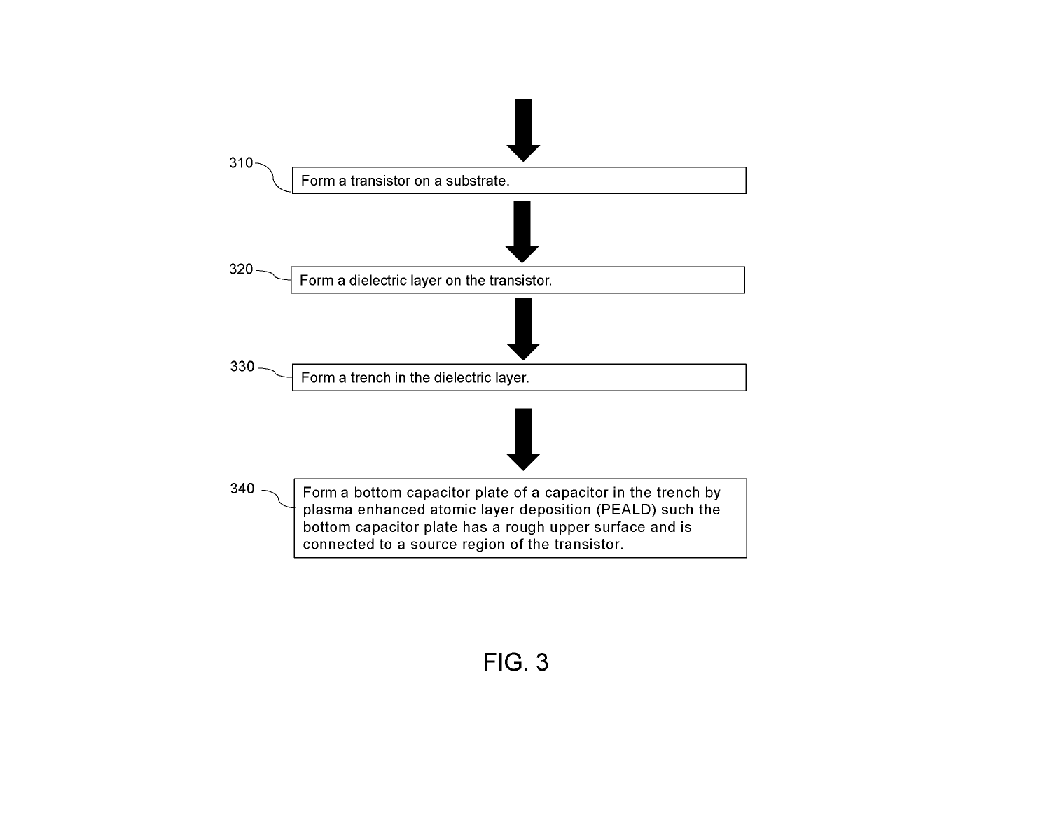

FIG. 3 illustrates a method of making a semiconductor device (e.g., semiconductor device 100), according to one or more embodiments. The method may include Step 310 of forming a transistor on a substrate, Step 320 of forming a dielectric layer on the transistor, Step 330 of forming a trench in the dielectric layer, and Step 340 of forming a bottom capacitor plate of a capacitor in the trench by plasma enhanced atomic layer deposition (PEALD) such the bottom capacitor plate has a rough upper surface and is connected to a source region of the transistor.

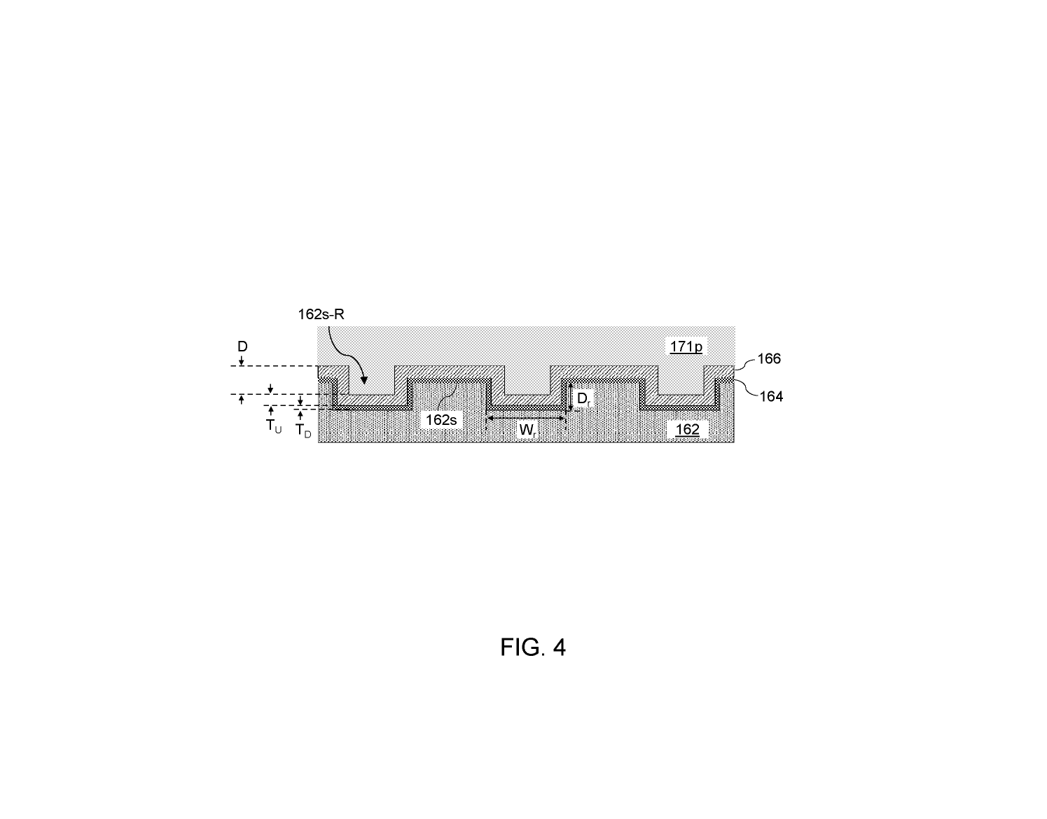

FIG. 4 is a detailed cross-sectional view of a portion of the capacitor 160 having an alternative design according to one or more embodiments. It should be noted that the recessed portion 162s-R are illustrated in FIG. 4 as having a regular configuration for ease of explanation. The recessed portion 162s-R may instead have an irregular configuration as illustrated in FIG. 1B. That is, the recesses in the recessed portion 162s-R may have varying depths and widths. The spaces between the recesses may also vary.

In the alternative design in FIG. 4, a width Wr of the recesses 162s-R may be greater than the depth Dr of the recesses 162s-R in the rough upper surface 162s of the bottom capacitor plate 162. The depth Dr of the recesses 162s-R may be greater than a thickness TD of the capacitor dielectric layer 164. In that case, at least a portion of the upper capacitor plate 166 may be located in the recesses 162-R on the capacitor dielectric layer 164.

In at least one embodiment, the depth Dr of the recesses 162s-R may be greater than a combined thickness including the thickness TD of the capacitor dielectric layer 164 and a thickness TU of the upper capacitor plate 166. In that case, at least a portion of the third dielectric layer projecting portion 171p may be located in the recesses 162s-R.

The width Wr of the recesses 162s-R may also be greater than the thickness TD of the capacitor dielectric layer 164. In at least one embodiment, the width Wr of the recesses 162s-R may be greater than twice the combined thickness including the thickness TD of the capacitor dielectric layer 164 and the thickness TU of the upper capacitor plate 166.

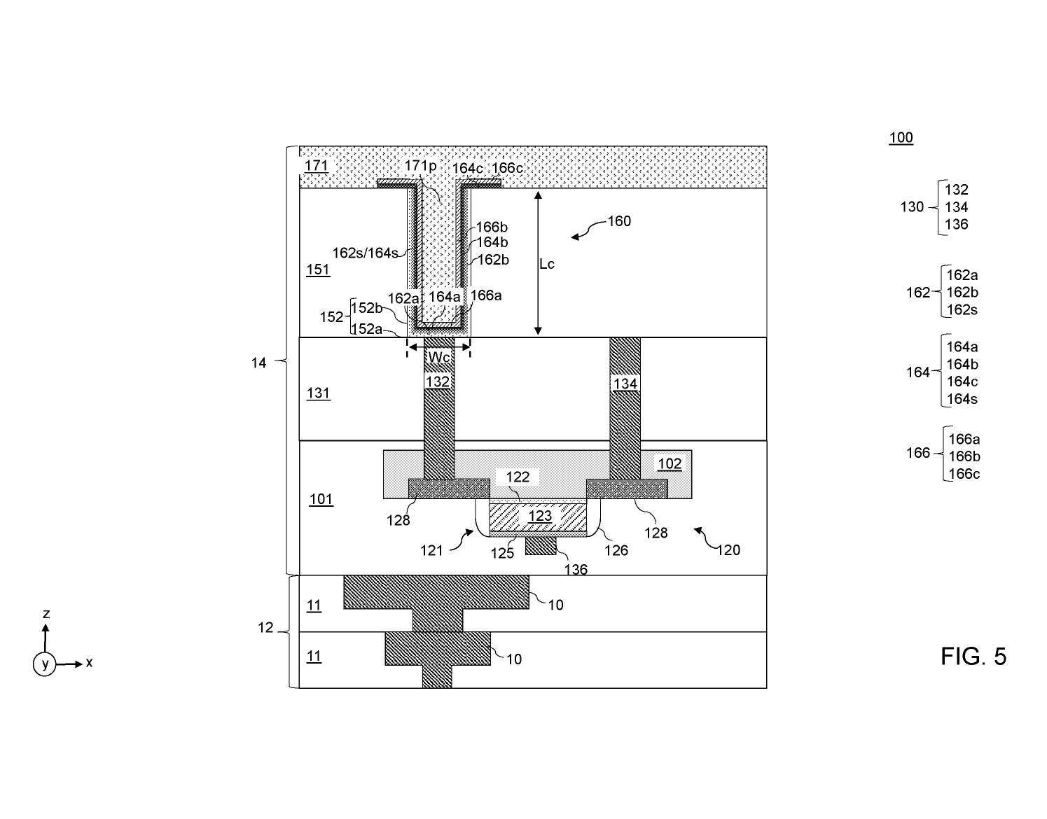

FIG. 5 is a vertical cross-sectional view of the semiconductor device 100 having a first alternative design according to one or more embodiments. As illustrated in FIG. 5, the second alternative design of the semiconductor device 100 may be substantially similar to the original design in FIG. 1A. However, in the first alternative design, the transistor 120 may have an inverted configuration in the dielectric layer 101 compared to the configuration in FIG. 1A.

In at least one embodiment, the elements of the transistor 120 in the first alternative design may be substantially the same as the elements in the original design in FIG. 1A. However, in the first alternative design, the gate structure 121 may be formed on an underside of the semiconductor material layer 102. The first source/drain contact 132 and the second source/drain contact 134 may contact the source/drain regions 128 through the semiconductor material layer 102.

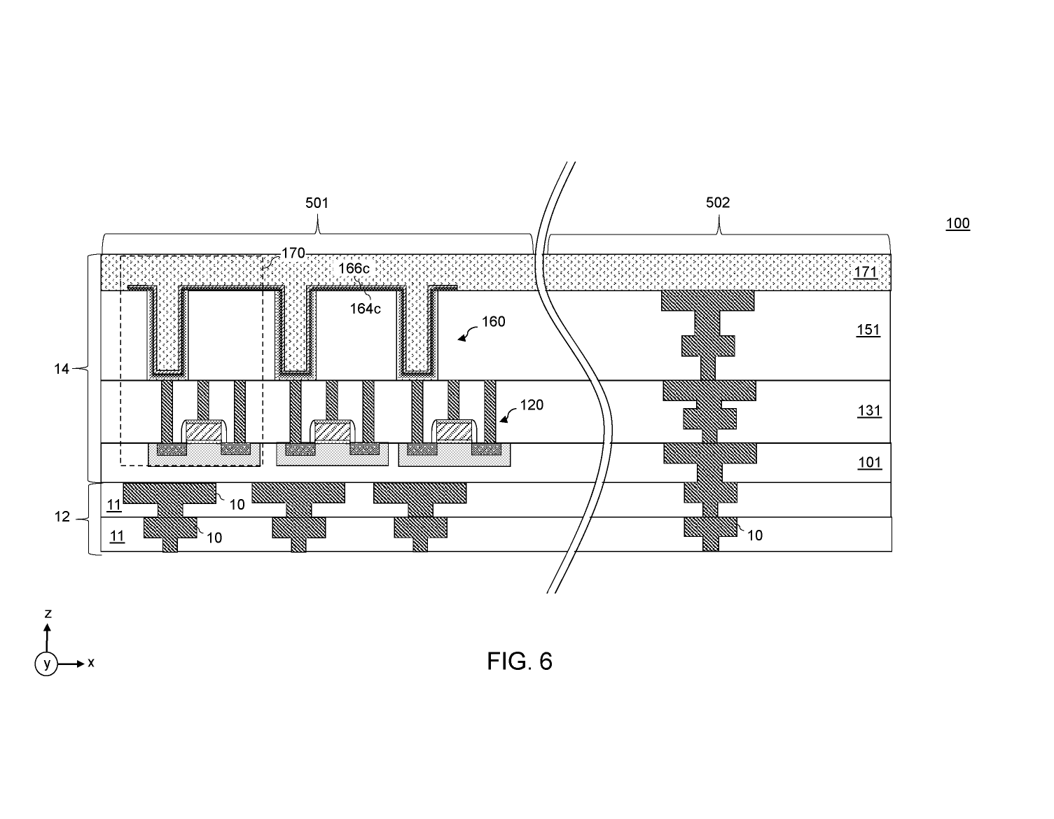

FIG. 6 is a vertical cross-sectional view of the semiconductor device 100 having a second alternative design according to one or more embodiments. As illustrated in FIG. 6, in the second alternative design, the semiconductor device 100 may include a memory section 501 and a logic section 502. In at least one embodiment, the logic section 502 may be formed adjacent the memory section 501 in the semiconductor device 100. In at least one embodiment, each of the memory section 501 and a logic section 502 may include the FEOL device circuitry 12 and the BEOL device circuitry 14.

The logic section 502 may include a plurality of logic devices (e.g., N-MOSFET devices, P-MOSFET devices, etc.) which are not shown in FIG. 6. The logic devices may be located in the active device area of the substrate (not shown) in the logic section 502. The logic section 502 may also include the interconnect metallization 10 in the FEOL device circuitry 12 and the BEOL device circuitry 14.

The memory section 501 may include a plurality of DRAM cells 170 in the BEOL device circuitry 14. The DRAM cells 170 may include the transistor 120 (e.g., select transistor) and the capacitor 160 for information storage. As illustrated in FIG. 5, the DRAM cells 170 may be formed adjacent to each other in the BEOL device circuitry 14.

In at least one embodiment, the capacitor dielectric layer upper portion 164c of the DRAM cells 170 may be electrically coupled together. In at least one embodiment the capacitor dielectric layer upper portion 164c of the DRAM cells 170 may be integrally formed together as a unit. In at least one embodiment, the capacitor dielectric layer upper portion 164c of the DRAM cells 170 may be formed concurrently in the same processing step.

In at least one embodiment, the upper capacitor plate upper portion 166c of the DRAM cells 170 may be electrically coupled together. In at least one embodiment the upper capacitor plate upper portion 166c of the DRAM cells 170 may be integrally formed together as a unit. In at least one embodiment, the upper capacitor plate upper portion 166c of the DRAM cells 170 may be formed concurrently in the same processing step.

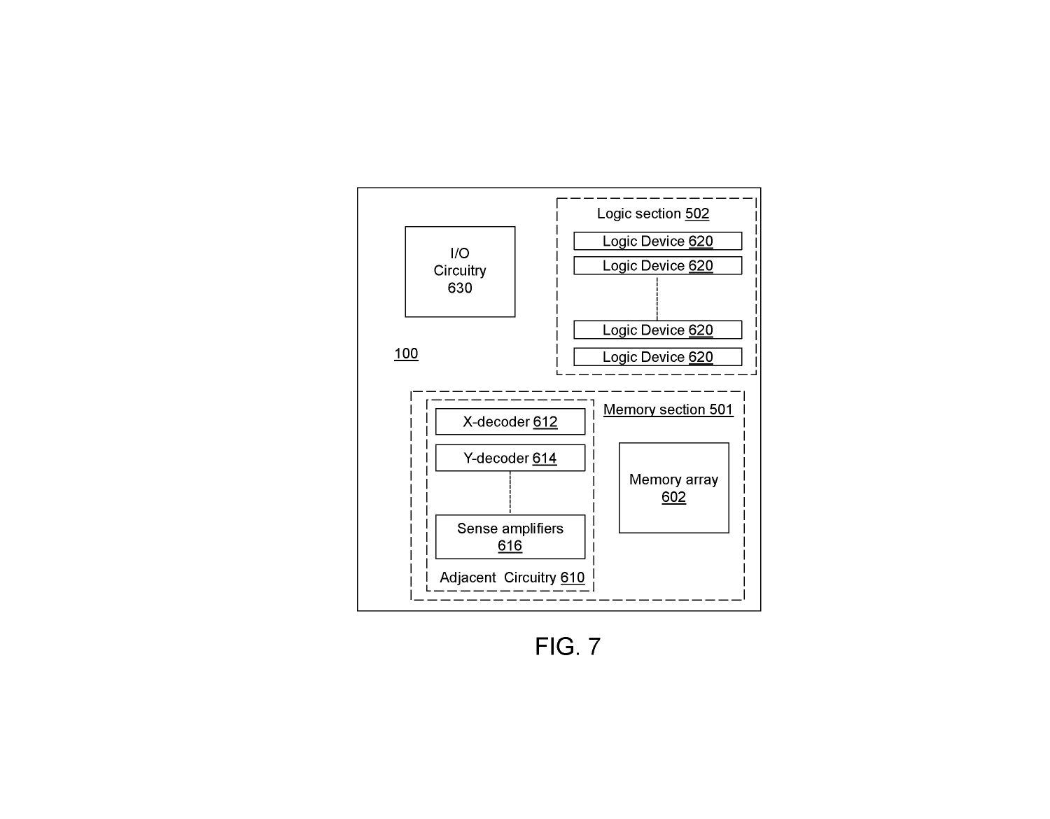

FIG. 7 is a schematic illustration of the semiconductor device 100 having a third alternative design according to one or more embodiments. As illustrated in FIG. 7, the semiconductor device 100 may include a system on chip (SOC) device including the memory section 501 and logic section 502. In at least one embodiment, the semiconductor device 100 may include a DRAM-incorporated logic chip.

In the third alternative design of the semiconductor device 100, the logic section 501 may be located adjacent the memory section 501. The logic section 501 may be capable of performing processing operations (e.g., graphic processing operations) at a high speed. The logic section 501 may utilize the memory section for storing information (e.g., information used in the processing operations, information generated by the processing operations, etc.).

The DRAM section 501 may include a memory array 602 including the plurality of the DRAM cells 170. The DRAM cells 170 may include the transistor 120 and capacitor 160 as illustrated, for example, in FIG. 6. The DRAM section 501 may also include adjacent circuitry 610 including, for example, an X-decoder 612, Y-decoder 614, sense amplifiers 616. The semiconductor device 100 may further include an input/output (I/O) section 630 adjacent the memory section 501 and the logic section 501. The I/O section 630 may, for example, connect the memory section 501 and the logic section 501 to an external circuit (not shown).

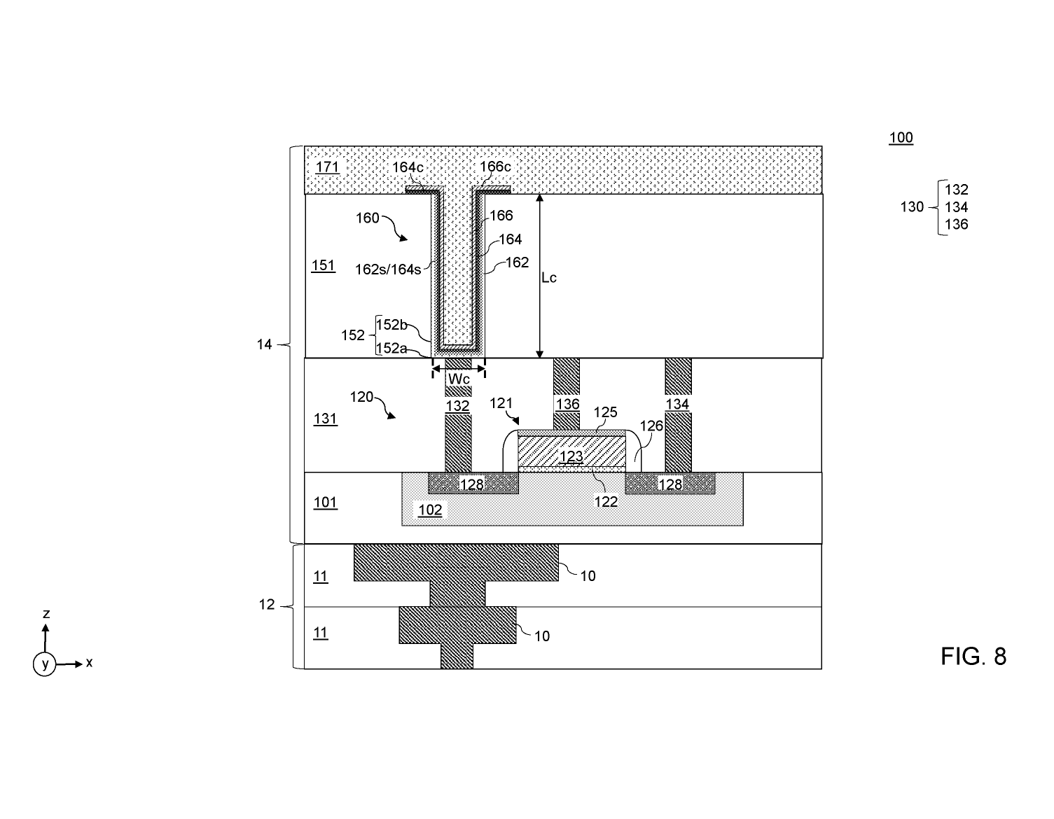

FIG. 8 is a schematic illustration of the semiconductor device 100 having a fourth alternative design according to one or more embodiments. As illustrated in FIG. 8, in the fourth alternative design, the bottom capacitor plate 162, the capacitor dielectric layer 164 and the upper capacitor plate 166 may substantially fill the trench 152. In this case, the third dielectric layer 171 may not project into the trench 152 as in the original design of FIG. 1A. In at least one embodiment, the capacitor 160 in the fourth alternative design may have a width Wc less than about 50nm (e.g., about 20nm). In at least one embodiment, the bottom capacitor plate 162 may have a thickness of about 2nm to 4nm, the capacitor dielectric layer 164 may have a thickness of about 2nm to 4nm, and the upper capacitor plate 166 may have a thickness of about 2nm to 4nm. In this case, where the capacitor 160 has a relatively small width (e.g., Wc=20), the trench 152 may be substantially filled by the bottom capacitor plate 162, capacitor dielectric layer 164 and upper capacitor plate 166.

Referring to FIGS. 1A-8, a capacitor 160 may include a bottom capacitor plate 162 including a rough upper surface 162s with a root mean square (RMS) surface roughness of at least 1.14, a capacitor dielectric layer 164 on the bottom capacitor plate 162 and contacting the rough upper surface 162s of the bottom capacitor plate 162, and an upper capacitor plate 166 on the capacitor dielectric layer 164. The bottom capacitor plate 162 may include a TiN layer and the rough upper surface 162s of the bottom capacitor plate 162 may include an upper surface of the TiN layer. The capacitor 160 may have a capacitance of 10.52fF or more. The rough upper surface 162s of the bottom capacitor plate 162 may include the recessed portion 162s-R and the capacitor dielectric layer 164 may be located in the recessed portion 162s-R. A depth Dr of the recessed portion 162s-R may be greater than a combined thickness of the capacitor dielectric layer 164 and the upper capacitor plate 166. A width Dr of the recessed portion 162s-R may be greater than twice the combined thickness of the capacitor dielectric layer 164 and the upper capacitor plate 166.

Referring again to FIGS. 1A-8, a semiconductor device 100 may include a transistor 120 located on a substrate, a dielectric layer 131,151 on the transistor 120, and a capacitor 160 in the dielectric layer 131,151 and including a bottom capacitor plate 162 connected to a source region 128 of the transistor 120 and having a rough upper surface 162s with a root mean square (RMS) surface roughness of at least 1.14. The capacitor 160 may further include a capacitor dielectric layer 164 on the bottom capacitor plate 162, the rough upper surface 162s may include the recessed portion

162s-R and the capacitor dielectric layer 164 may be located in the recessed portion 162s-R. The capacitor 160 may further include an upper capacitor plate 166 on the capacitor dielectric layer 164 and in the recessed portion 162s-R. The dielectric layer 131,151 may include a trench 152 having a substantially cylindrical shape and the capacitor 160 may include a trench capacitor having a substantially cylindrical shape in the trench 152 of the dielectric layer 131,151. The trench 152 may include a trench bottom 152a and a trench sidewall 152b extending upward from the trench bottom 152a, and the bottom capacitor plate 162 may include a substantially cylindrical shape and may include a bottom capacitor plate bottom portion 162a contacting the trench bottom 152a and a bottom capacitor plate sidewall portion 162b contacting the trench sidewall 152b. The capacitor dielectric layer 164 may include a substantially cylindrical shape and may include a capacitor dielectric layer bottom portion 164a contacting the bottom capacitor plate bottom portion 162a, and a capacitor dielectric layer sidewall portion 164b contacting the bottom capacitor plate sidewall portion 162b. The rough upper surface 162s of the bottom capacitor plate 162 may contact the capacitor dielectric layer bottom portion 164a and the capacitor dielectric layer sidewall portion 164b. The upper capacitor plate 166 may include a substantially cylindrical shape and may include an upper capacitor plate bottom portion 166a contacting the capacitor dielectric layer bottom portion 164a, and an upper capacitor plate sidewall portion 166b contacting the capacitor dielectric layer sidewall portion 164b. The semiconductor device 100 may further include a first contact 132 in the dielectric layer 131,151 and connecting the source region 128 of the transistor 120 to the bottom capacitor plate bottom portion 162a.

Referring again to FIGS. 1A-8, a method of making a semiconductor device 100 may include forming a transistor 120 on a substrate 102, forming a dielectric layer 131,151 on the transistor 120, forming a trench 152 in the dielectric layer 131, 151, and forming a bottom capacitor plate 162 of a capacitor 160 in the trench 152 by plasma enhanced atomic layer deposition (PEALD) such the bottom capacitor plate 162 has a rough upper surface 162s and is connected to a source region 128 of the transistor. The forming of the bottom capacitor plate 162 may include depositing a TiN layer in the trench, the rough upper surface 162s of the bottom capacitor plate 162 may include an upper surface of the TiN layer, and the rough upper surface 162s may have a root mean square (RMS) surface roughness of at least 1.14. The method may further include forming a capacitor dielectric layer 164 on the rough upper surface 162s of the bottom capacitor plate 162. The forming of the bottom capacitor plate 162 may include forming the rough upper surface 162s to have a recessed portion 162s-R, and the forming of the capacitor dielectric layer 164 may include forming the capacitor dielectric layer 164 in the recessed portion 162s-R of the rough upper surface 162s. The method may further include forming an upper capacitor plate 166 on the capacitor dielectric layer 164 and in the recessed portion 162s-R of the rough upper surface 162s.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not

depart from the spirit and scope of the present disclosure, and that they may make various changes, substitutions, and alterations herein without departing from the spirit and scope of the present disclosure.

What is claimed is:

1. A capacitor, comprising:
a bottom capacitor plate including a rough upper surface with a root mean square (RMS) surface roughness of at least 1.14;
a capacitor dielectric layer on the bottom capacitor plate and contacting the rough upper surface of the bottom capacitor plate; and
an upper capacitor plate on the capacitor dielectric layer.

2. The capacitor of claim 1, wherein the bottom capacitor plate comprises a TiN layer and the rough upper surface of the bottom capacitor plate includes an upper surface of the TiN layer.

3. The capacitor of claim 2, wherein the capacitor has a capacitance of 10.52fF or more.

4. The capacitor of claim 1, wherein the rough upper surface of the bottom capacitor plate comprises a recessed portion and the capacitor dielectric layer is located in the recessed portion.

5. The capacitor of claim 4, wherein a depth of the recessed portion is greater than a combined thickness of the capacitor dielectric layer and the upper capacitor plate.

6. The capacitor of claim 5, wherein a width of the recessed portion is greater than twice the combined thickness of the capacitor dielectric layer and the upper capacitor plate.

7. A semiconductor device, comprising:
a transistor located on a substrate;
a dielectric layer on the transistor; and
a capacitor in the dielectric layer and including a bottom capacitor plate connected to a source region of the transistor and having a rough upper surface with a root mean square (RMS) surface roughness of at least 1.14.

8. The semiconductor device of claim 7, wherein the capacitor further comprises a capacitor dielectric layer on the bottom capacitor plate, the rough upper surface includes a recessed portion and the capacitor dielectric layer is located in the recessed portion.

9. The semiconductor device of claim 8, wherein the capacitor further comprises an upper capacitor plate on the capacitor dielectric layer and in the recessed portion.

10. The semiconductor device of claim 9, wherein the dielectric layer comprises a trench having a substantially cylindrical shape and the capacitor comprises a trench capacitor having a substantially cylindrical shape in the trench of the dielectric layer.

11. The semiconductor device of claim 10, wherein the trench comprises a trench bottom and a trench sidewall extending upward from the trench bottom, and the bottom capacitor plate comprises a substantially cylindrical shape and includes a bottom capacitor plate bottom portion contacting the trench bottom and a bottom capacitor plate sidewall portion contacting the trench sidewall.

12. The semiconductor device of claim 11, wherein the capacitor dielectric layer comprises a substantially cylindrical shape and includes a capacitor dielectric layer bottom portion contacting the bottom capacitor plate bottom portion, and a capacitor dielectric layer sidewall portion contacting the bottom capacitor plate sidewall portion.

13. The semiconductor device of claim 12, wherein the rough upper surface of the bottom capacitor plate contacts the capacitor dielectric layer bottom portion and the capacitor dielectric layer sidewall portion.

14. The semiconductor device of claim 12, wherein the upper capacitor plate comprises a substantially cylindrical shape and includes an upper capacitor plate bottom portion contacting the capacitor dielectric layer bottom portion, and an upper capacitor plate sidewall portion contacting the capacitor dielectric layer sidewall portion.

15. The semiconductor device of claim 11, further comprising:
a first contact in the dielectric layer and connecting the source region of the transistor to the bottom capacitor plate bottom portion.

16. A semiconductor device, comprising:
front-end-of-line (FEOL) device circuitry; and
back-end-of-line (BEOL) device circuitry on the FEOL device circuitry, the BEOL device circuitry including a transistor and a capacitor, the capacitor including a bottom capacitor plate having a rough upper surface with a root mean square (RMS) surface roughness of at least 1.14.

17. The semiconductor device of claim 16, wherein the transistor and the capacitor constitute a 1-transistor/1-capacitor (1T1C) memory cell.

18. The semiconductor device of claim 16, wherein the FEOL device circuitry includes one or more dielectric material layers and one or more levels of interconnect metallization formed in and electrically insulated by the one or more dielectric material layers.

19. The semiconductor device of claim 16, wherein the bottom capacitor plate is connected to a source region of the transistor through a first contact in the BEOL device circuitry.

20. The semiconductor device of claim 16, wherein the bottom capacitor plate comprises a TiN layer and the rough upper surface of the bottom capacitor plate comprises an upper surface of the TiN layer.
